(19) United States
(12) Patent Application Publication
(10) Pub. No.: US 2025/0268079 A1
(43) Pub. Date: Aug. 21, 2025

(54) DISPLAY APPARATUS AND ELECTRONIC DEVICE

(71) Applicant: Semiconductor Energy Laboratory Co., Ltd., Atsugi-shi (JP)

(72) Inventors: Ryo HATSUMI, Hadano (JP); Daiki NAKAMURA, Atsugi (JP); Tetsuji ISHITANI, Atsugi (JP); Mitsuhiro MATSUKI, Atsugi (JP); Hidekazu MIYAIRI, Hadano (JP)

(21) Appl. No.: 19/046,558

(22) Filed: Feb. 6, 2025

(30) Foreign Application Priority Data
Feb. 21, 2024 (JP) 2024-024199

(51) Int. Cl. H10K 59/80; H10K 50/19; H10K 59/35

(52) U.S. Cl. CPC H10K 59/879; H10K 50/19; H10K 59/35

(57) ABSTRACT

A display apparatus with high light extraction efficiency is provided. The display apparatus includes first to third subpixels in a pixel. The first and second subpixels are disposed to be adjacent to each other in a first direction. The third subpixel is disposed to be adjacent to each of the first and second subpixels in a second direction that intersects perpendicularly with the first direction. A first plano-convex lens is disposed over the first subpixel, a second plano-convex lens is disposed over the second subpixel, and a third plano-convex lens and a fourth plano-convex lens are disposed to be adjacent to each other over the third subpixel, whereby light extraction efficiency can be increased.

### BACKGROUND OF THE INVENTION

### 1. Field of the Invention

One embodiment of the present invention relates to a display apparatus and an electronic device.

### 2. Description of the Related Art

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display apparatus, a liquid crystal display apparatus, a light-emitting device, a lighting device, a power storage device, a memory device, an image capturing device, a method for operating any of them, and a method for manufacturing any of them.

In this specification and the like, a semiconductor device generally means a device that can function by utilizing semiconductor characteristics. A transistor and a semiconductor circuit are embodiments of semiconductor devices. In some cases, a memory device, a display apparatus, an image capturing device, or an electronic device includes a semiconductor device.

### 2. Description of the Related Art

Goggles-type devices and glasses-type devices have been developed as electronic devices for extended reality (XR). Note that XR is a general term for virtual reality (VR), augmented reality (AR), mixed reality (MR), and the like.

Typical examples of display panels that can be used for these electronic devices include a display apparatus including a liquid crystal element and a display apparatus including an organic electroluminescent (EL) element, a light-emitting diode (LED), or the like.

A display apparatus including an organic EL element does not need a backlight, which is necessary for a liquid crystal display apparatus, and thus can have advantages such as thinness, lightweight, high contrast, and low power consumption. Patent Document 1, for example, discloses an example of a display apparatus including an organic EL element.

### REFERENCE

### [Patent Document]

[Patent Document 1] Japanese Published Patent Application No. 2018-107444

### SUMMARY OF THE INVENTION

A catadioptric system used in VR devices or the like utilizes selective reflection of polarized light, for example; thus, the light utilization efficiency is not sufficient. In addition, AR devices are required to have high visibility of display even when external light is intense. Accordingly, the luminance of a display apparatus in an XR device needs to be increased in use. Increasing the luminance of a display apparatus might cause an increase in power consumption and a decrease in reliability of a display device, and thus a display apparatus with high light extraction efficiency has been desired.

Thus, one object of one embodiment of the present invention is to provide a display apparatus with high light extraction efficiency. Another object is to provide a display apparatus with low power consumption. Another object is to provide a display apparatus with high visibility. Another object is to provide an electronic device including any of the above-described display apparatuses. Another object is to provide a novel electronic device.

Note that the description of these objects does not preclude the presence of other objects. In one embodiment of the present invention, there is no need to achieve all of these objects. Other objects will be apparent from and can be derived from the description of the specification, the drawings, the claims, and the like.

One embodiment of the present invention relates to a display apparatus with high light extraction efficiency.

One embodiment of the present invention is a display apparatus including a pixel. The pixel includes a first subpixel, a second subpixel, and a third subpixel that emit light of different colors. The first subpixel and the second subpixel are disposed to be adjacent to each other in a first direction. The third subpixel is disposed to be adjacent to each of the first subpixel and the second subpixel in a second direction intersecting with the first direction perpendicularly. A first plano-convex lens is disposed over the first subpixel. A second plano-convex lens is disposed over the second subpixel. A third plano-convex lens and a fourth plano-convex lens are disposed over the third subpixel to be adjacent to each other in the first direction.

The third plano-convex lens is preferably disposed to be adjacent to the first plano-convex lens in the second direction. The fourth plano-convex lens is preferably disposed to be adjacent to the second plano-convex lens in the second direction. The first plano-convex lens and the fourth plano-convex lens each preferably have a circular outline with a radius r₁ in a top view. The second plano-convex lens and the third plano-convex lens each preferably have a circular outline with a radius r₂ in the top view. The pixel preferably has a square shape in the top view. A length of one side of the pixel is preferably larger than or equal to 2(r₁+r₂).

A region of the third plano-convex lens can be positioned over an adjacent pixel. The first plano-convex lens, the second plano-convex lens, the third plano-convex lens, and the fourth plano-convex lens are each preferably a spherical lens.

The third subpixel preferably has a rectangular shape in the top view. A center point of each of the third plano-convex lens and the fourth plano-convex lens is preferably positioned on or in a vicinity of a straight line perpendicularly dividing a short side of the third subpixel in the top view. The center point of the third plano-convex lens is preferably positioned with a distance of r₂ from a center point of the third subpixel or in the vicinity thereof in the top view. The center point of the fourth plano-convex lens is preferably positioned with a distance of r₁ from the center point of the third subpixel or in the vicinity thereof in the top view.

Another embodiment of the present invention is a display apparatus including a pixel. The pixel includes a first subpixel, a second subpixel, and a third subpixel emitting light of different colors. The first subpixel and the second subpixel are disposed to be adjacent to each other in a first direction. The third subpixel is disposed to be adjacent to each of the first subpixel and the second subpixel in a second direction intersecting with the first direction perpendicularly. A first plano-convex lens is disposed over the first subpixel. A second plano-convex lens is disposed over the second subpixel. A lens array is disposed over the third subpixel. The lens array includes three different plano-convex lenses bonded in the first direction. The lens array includes a first lens region, a second lens region, and a third lens region having different curvatures in this order in the first direction.

The first lens region preferably includes a region with a first curvature. The second lens region preferably includes a region with a second curvature. The third lens region preferably includes a region with a third curvature. The region with the first curvature preferably has a curvature equivalent to a curvature of the second plano-convex lens. The region with the third curvature preferably has a curvature equivalent to a curvature of the first plano-convex lens. The second lens region preferably has a curvature in a range between the curvature of the first plano-convex lens and the curvature of the second plano-convex lens.

The first lens region is preferably disposed to be adjacent to the first plano-convex lens in the second direction. The third lens region is preferably disposed to be adjacent to the second plano-convex lens in the second direction. The first plano-convex lens preferably has a circular outline with a radius r₁ in a top view. The second plano-convex lens preferably has a circular outline with a radius r₂ in the top view. The pixel preferably has a square shape in the top view. A length of one side of the pixel is preferably larger than or equal to 2(r₁+r₂).

A region of the lens array can be positioned over an adjacent pixel.

The third subpixel preferably has a rectangular shape in the top view. A center point of each of the first lens region, the second lens region, and the third lens region is preferably positioned on or in a vicinity of a straight line perpendicularly dividing a short side of the third subpixel in the top view. The center point of the second lens region is preferably positioned at or in a vicinity of a center point of the third subpixel in the top view.

One of a first light-emitting element and a second light-emitting element preferably emits red light. The other of the first light-emitting element and the second light-emitting element preferably emits green light. A third light-emitting element preferably emits blue light.

Another embodiment of the present invention is an electronic device in which any one of the above-described display apparatuses is used as a light source and a catadioptric system is provided on a display surface side of the display apparatus.

One embodiment of the present invention can provide a display apparatus with high light extraction efficiency. A display apparatus with low power consumption can be provided. A display apparatus with high visibility can be provided. An electronic device including any of the above-described display apparatuses can be provided. A novel electronic device can be provided.

Note that the description of these effects does not preclude the presence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIG. 1 is a diagram illustrating pixels of a display apparatus;

FIGS. 2A and 2B are diagrams illustrating pixels with S-stripe arrangement;

FIGS. 3A to 3D are diagrams illustrating arrangement of lenses;

FIGS. 4A1, 4A2, 4B1, 4B2, 4C1, and 4C2 are diagrams illustrating simulation models;

FIG. 5 is a diagram illustrating a simulation model;

FIG. 6 is a graph showing simulation results;

FIG. 7 is a diagram illustrating pixels of a display apparatus;

FIGS. 8A and 8B are diagram illustrating pixels with S-stripe arrangement;

FIGS. 9A and 9B are diagrams illustrating arrangement of lenses;

FIG. 10 is a graph showing simulation results;

FIGS. 11A to 11C are diagrams illustrating a display apparatus;

FIGS. 12A to 12E are diagrams illustrating a formation method of a lens;

FIGS. 13A and 13B are diagrams each illustrating display apparatuses;

FIGS. 14A to 14E are diagrams each illustrating display panels;

FIGS. 15A to 15C are diagram each illustrating a glasses-type device;

FIGS. 16A and 16B are diagrams illustrating a structure example of a display panel;

FIG. 17 is a diagram illustrating a structure example of a display panel;

FIG. 18 is a diagram illustrating a structure example of a display panel;

FIG. 19 is a diagram illustrating a structure example of a display panel;

FIG. 20 is a diagram illustrating a structure example of a display panel;

FIG. 21 is a diagram illustrating a structure example of a display panel;

FIG. 22 is a diagram illustrating a structure example of a display panel; and

FIGS. 23A and 23B are diagrams illustrating a transistor.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Accordingly, the present invention should not be construed as being limited to the description in the following embodiments. Note that in structures of the invention described below, the same portions or portions having similar functions are denoted by the same reference numerals in different drawings, and the description thereof is not repeated in some cases. The same components are denoted by different hatching patterns in different drawings, or the hatching patterns are omitted in some cases.

Even in the case where a single component is illustrated in a circuit diagram, the component may be composed of a plurality of parts as long as there is no functional inconvenience. For example, in some cases, a plurality of transistors that operate as a switch are connected in series or in parallel. In some cases, capacitors are divided and arranged in a plurality of positions.

One conductor has a plurality of functions such as a wiring, an electrode, and a terminal in some cases. In this specification, a plurality of names are used for the same component in some cases. Even in the case where components are illustrated in a circuit diagram as if they were directly connected to each other, the components may actually be connected to each other through one or more conductors. In this specification, even such a structure is included in direct connection.

The expression “connection” in this specification includes “electrical connection”, for example. Note that the expression “electrical connection” is used in some cases to specify the connection relation of a circuit element as an object. The term “electrical connection” includes “direct connection” and “indirect connection”. The expression “A and B are directly connected” means that A and B are connected to each other without a circuit element (e.g., a transistor or a switch; a wiring is not a circuit element) therebetween. By contrast, the expression “A and B are indirectly connected” means that A and B are connected to each other with at least one circuit element therebetween.

For example, assuming that a circuit including A and B is in operation, the circuit can be specified as “A and B are indirectly connected” as an object when electric signal transmission and reception or electric potential interaction between A and B occurs at some point during the operation period of the circuit. Note that even when neither electric signal transmission and reception nor electric potential interaction between A and B occurs at some point during the operation of the circuit, the circuit can be specified as “A and B are indirectly connected” as long as electric signal transmission and reception or electric potential interaction between A and B occurs at another point during the operation period of the circuit.

Examples of the case where the expression “A and B are indirectly connected” can be used include the case where A and B are connected to each other through a source and a drain of at least one transistor. By contrast, examples of the case where the expression “A and B are indirectly connected” cannot be used include the case where an insulator is present on the path from A to B. Specific examples thereof include the case where a capacitor is connected between A and B and the case where a gate insulating film of a transistor or the like is present between A and B. In such cases, the expression “a gate (A) of a transistor and a source or a drain (B) of the transistor are indirectly connected” cannot be used.

Another example of the case where the expression “A and B are indirectly connected” cannot be used is the case where a plurality of transistors are connected through their sources and drains on the path from A to B and a constant electric potential V is supplied from a power source, GND, or the like to a node between one of the transistors and another one of the transistors.

In this specification, a square includes a substantially square shape, and a rectangle includes a substantially rectangular shape. A substantially square shape refers to one of a square, a modified square shape whose corner has a curvature, and a modified square shape whose one or more sides each have a curvature or a shape combining two of these shapes. A substantially rectangular shape refers to one of a rectangle, a modified rectangular shape whose corner have a curvature, and a modified rectangular shape whose one or more sides each have a curvature or a shape combining two of these shapes. Moreover, a circle is not limited to a perfect circle and includes a substantially circular shape having a plurality of curvatures in its circumference.

### Embodiment 1

In this embodiment, a display apparatus and an electronic device of one embodiment of the present invention will be described.

One embodiment of the present invention is a display apparatus with high light extraction efficiency. The display apparatus includes spherical lenses over subpixels. The spherical lenses are provided for respective subpixels that emit light of different colors, and a spherical lens with a circular shape in a top view or a lens array in which a plurality of spherical lenses are bonded can be used.

The lens provided over the subpixel is preferably a hemispherical lens that enables light, which has been emitted obliquely from a light-emitting element, to be strongly refracted in the front direction. However, in pixel arrangement where the shapes of subpixels are not uniform such as S-stripe arrangement, an appropriate hemispherical lens cannot be disposed for each subpixel because of pixel size limitation in some cases.

Thus, in one embodiment of the present invention, a spherical lens, a plurality of spherical lenses, or a lens array in which a plurality of spherical lenses are bonded is provided over a subpixel. With the use of such a lens or a lens array, light from a light-emitting element is efficiently directed in the front direction even when the shapes of subpixels included in a pixel are not uniform.

With the use of the spherical lens or the lens array of one embodiment of the present invention, loss of the light emitted from the light-emitting element due to divergence and reflection can be inhibited, so that the light extraction efficiency of the display apparatus can be increased. With this action, it is possible to reduce a voltage applied to the light-emitting element, resulting in an increase in the reliability of the light-emitting element and a reduction in the power consumption of the light-emitting element. Furthermore, an XR device and the like can achieve higher visibility with the use of the display apparatus.

Note that all the lenses used in one embodiment of the present invention are plano-convex lenses, and description for each lens is omitted in some cases.

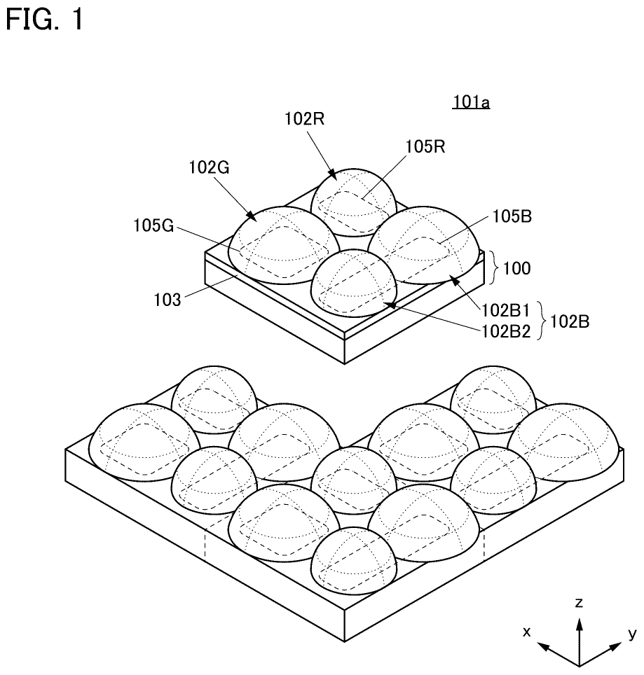

FIG. 1 is a perspective view of part of a pixel array included in the display apparatus of one embodiment of the present invention, where a pixel 101a is extracted. Note that a pixel is a minimum unit of an image whose color and brightness can be controlled. The pixel 101a includes a subpixel 105R including a light-emitting element emitting red light, a subpixel 105G including a light-emitting element emitting green light, and a subpixel 105B including a light-emitting element emitting blue light. Lenses 102 (lenses 102R, 102G, and 102B) are provided over the subpixels. The lens 102R is provided over the subpixel 105R, the lens 102G is provided over the subpixel 105G, and the lenses 102B (lenses 102B1 and 102B2) are provided over the subpixel 105B. Note that a stack 100 includes components included in the pixel 101a.

An insulating layer 103 included in the stack 100 is an insulating layer provided between the light-emitting element and the lens 102 and has a visible-light-transmitting property. Since the insulating layer 103 is on the optical path, the insulating layer 103 and the lens 102 have optical interaction with light emitted from the light-emitting element.

The lens 102 is a plano-convex lens and has a minute size in accordance with the size of a pixel; thus, the lens 102 is also referred to as a microlens. The structure in which the plano-convex lenses are regularly arranged on a plane is referred to as a microlens array (MLA).

Although as a typical example of the arrangement of subpixels with different shapes, S-stripe arrangement is used in this embodiment, stripe arrangement, delta arrangement, zigzag arrangement, PenTile arrangement, diamond arrangement, or the like can be employed regardless of the shapes of subpixels.

A pixel with S-stripe arrangement includes first to third subpixels that emit light of different colors. The first and second subpixels are disposed to be adjacent to each other in a first direction, and the third subpixel is disposed to be adjacent to each of the first and second subpixels in a second direction that intersects with the first direction perpendicularly.

S-stripe arrangement has an advantage in terms of increasing the luminance of a display panel, as it can reduce the area between subpixels more easily than stripe arrangement, for example, and thus has a higher aperture ratio.

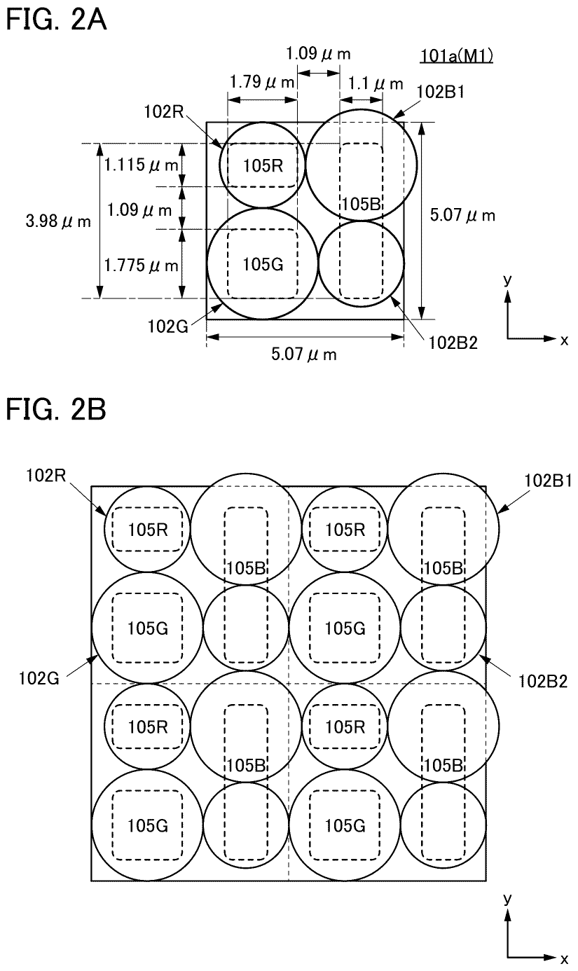

FIG. 2A is an example of a top view of a pixel with S-stripe arrangement and illustrates a layout of the pixel 101a that can be used in a display panel with 5009 ppi. The pixel 101a includes the subpixel 105R including a light-emitting element emitting red light (e.g., a wavelength of 625 nm to 780 nm), the subpixel 105G including a light-emitting element emitting green light (e.g., a wavelength of 500 nm to 565 nm), and the subpixel 105B including a light-emitting element emitting blue light (e.g., a wavelength of 450 nm to 485 nm).

The lifetime of a light-emitting element correlates with the current density at the time of light emission. Thus, a subpixel including a light-emitting element with relatively high reliability preferably has a small occupied area (element area) in a pixel and obtains necessary luminance by increasing the current density. A subpixel including a light-emitting element with relatively low reliability preferably has a large occupied area in a pixel and obtains necessary luminance by reducing the current density.

For example, the area occupied by the subpixel 105R including the light-emitting element that emits red light and has the highest reliability is made the smallest, and the area occupied by the subpixel 105R including the light-emitting element that emits blue light and has the lowest reliability is made the largest as illustrated in FIG. 2A. The area occupied by subpixels is preferably varied according to the emission color in such a manner so that a lifetime extension can be achieved as a whole.

Since a catadioptric system used in VR devices or the like utilizes selective reflection of polarized light, for example, the light utilization efficiency is not sufficient. In addition, AR devices are required to have high visibility of display even when external light is intense. In addition, a display panel used in an XR device required to have a definition higher than or equal to 2000 ppi in order to inhibit a screen-door effect, for example. On the other hand, a smaller pixel size lowers the aperture ratio. Thus, when the density of a current flowing through the light-emitting element is constant, the amount of light incident on an optical system is insufficient. Accordingly, a display panel required to have increased luminance.

Provision of a convex lens over a light-emitting element is effective to increase the front luminance of a display panel. Part of light from the light-emitting element that is emitted in an oblique direction is totally reflected by an interface in the display panel and reflected or absorbed by components, resulting in a failure to extract the light to the outside. Provision of a convex lens enables the light emitted from the light-emitting element in an oblique direction to be refracted in the direction towards the top surface of the display panel. That is, the front luminance can be increased.

As the convex lens, a hemispherical lens with a high curvature enabling great refraction is ideal. However, the shapes of the subpixels provided in the pixel are different from each other in S-stripe arrangement as described above, and thus a hemispherical lens cannot be easily disposed.

In the case where hemispherical lenses each covering the subpixel are arranged, adjacent hemispherical lenses are bonded to each other, resulting in loss of part of a function of the lens. In addition, the paths of light emitted from subpixels becomes complicated, which might cause light incidence on an adjacent pixel, that is, color mixing.

Thus, in one embodiment of the present invention, a spherical lens with a circular shape in a top view covering the subpixel is used as each of the subpixel 105R and the subpixel 105G with a square or a rectangular shape having a relatively low aspect ratio in the top view as illustrated in FIG. 2A. For the subpixel 105B with a rectangular shape having a relatively high aspect ratio in the top view, two spherical lenses disposed to be adjacent to each other are used. These spherical lenses preferably have a circular outline in a top view in order that refraction by the lens does not depend on the direction of light incidence.

A hemispherical lens is preferably used as the spherical lens. However, in the case where hemispherical lenses are provided to fit the size of the subpixels, hemispherical lenses with different heights depending on the size of the subpixels are provided. Repetition of the formation process for lenses with different heights leads to an increase in manufacturing cost; thus, a plurality of lenses are preferably formed in the same process.

A method for forming the lens is described later. The lens used in one embodiment of the present invention is formed by processing a material applied to a certain thickness into an island shape by a lithography process. Thus, the heights of the lenses are substantially the same.

Thus, a plano-convex spherical lens is used as the lens of one embodiment of the present invention. Note that a spherical lens used in one embodiment of the present invention refers to a lens with the shape of a segment of a sphere cut off and whose height is lower than or equal to that of a hemispherical lens. That is, a hemispherical lens is one of spherical lenses. In this embodiment, an example is described in which the lens with the smallest curvature radius is a hemispherical lens and the other lenses are spherical lenses whose heights are lower than that of the hemispherical lens.

Note that one embodiment of the present invention is not limited to a structure employing a hemispherical lens. For example, all the lenses may be spherical lenses that are not hemispherical or may be aspherical lenses. Depending on the shape of the subpixel, a lens combined with the subpixel may increase the angle dependence of chromaticity variation in white display. In that case, the use of a lens whose height is lower than that of a hemispherical lens to reduce the degree of refraction may attenuate the chromaticity variation.

In the lens 102B1 and the lens 102B2 provided over the subpixel 105B, the area covering the subpixel 105B is preferably as large as possible in order to collect as much light emitted from the light-emitting elements as possible. Accordingly, the sizes of the lens 102B1 and the lens 102B2 are not necessarily the same, and may be different from each other.

In all the lenses 102, the bottom area (the area of the plano-convex lens on the flat surface side) is preferably as large as possible in order to collect as much light emitted from the light-emitting elements as possible. Note that bonding of adjacent lenses causes color mixture; thus, the lenses 102 are preferably arranged densely such that adjacent lenses are in contact with each other.

FIG. 2B is an example of a top view illustrating four adjacent pixels 101a that are part of a pixel array. Thus, by selecting an appropriate lens size for each subpixel, lenses with circular shapes in a top view can be densely arranged.

Note that although some regions of the lens 102B1 extend beyond the outline of one pixel 101a as illustrated in FIGS. 2A and 2B, the regions can be positioned in unoccupied regions of adjacent pixels, and thus the lens 102B1 can be regarded as being disposed within the occupied area of the pixel 101a substantially.

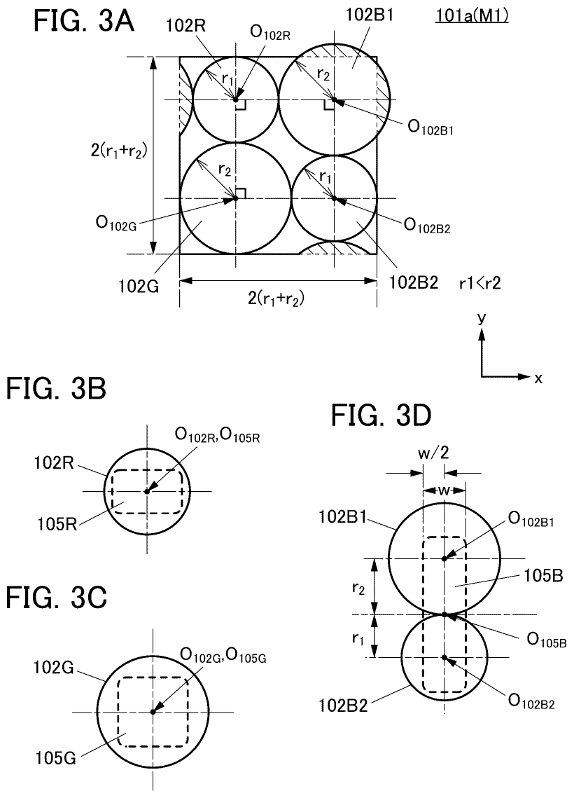

In order to make the bottom area of the lens 102 as large as possible and arrange the lenses densely as possible, the size of the lenses and the pixels is set appropriately. For example, as illustrated in the top view in FIG. 3A, when the radius of the bottom surface of the lens 102R is set to r₁ and the radius of the bottom surface of the lens 102G is set to r₂, the radius of the bottom surface of the lens 102B1 is set to r₂ and the radius of the bottom surface of the lens 102B2 is set to r₁.

Then, the lens 102R and the lens 102G are disposed to be adjacent to each other in the first direction (y direction), and the lens 102R and the lens 102B1 are disposed to be adjacent to each other in the second direction (x direction) that intersects with the first direction perpendicularly. The lens 102G and the lens 102B2 are disposed to be adjacent to each other in the second direction (x direction). At this time, a quadrangle having a center point O_{102R} of the lens 102R, a center point O_{102G} of the lens 102G, a center point O_{102B1} of the lens 102B1, and a center point O_{102B2} of the lens 102B2 as vertices is a square.

Furthermore, the pixel 101a is preferably a square and one side thereof is preferably 2(r₁+r₂), in which case the occupied area of the lens with respect to the pixel can be the largest. At this time, although some regions of the lens 102B1 extend beyond the occupied area of the pixel 101a, the regions can be positioned in unoccupied regions of the adjacent pixels 101a as indicated by hatched lines in FIG. 3A, and thus the lens 102B1 can be regarded as being disposed within the occupied area of the pixel 101a substantially.

Note that one side of the pixel 101a may be larger than 2(r₁+r₂); however, in this case, the area occupied by the lens is smaller than that in the case where one side of the pixel 101a is 2(r₁+r₂). In the case where one side of the pixel 101a is smaller than 2(r₁+r₂), adjacent lenses are bonded to each other, which is not preferable.

As illustrated in FIG. 3B, the center point O_{102R} of the lens 102R is preferably provided to overlap with a center point O_{105R} of the subpixel 105R. Alternatively, the center point O_{102R} of the lens 102R is preferably provided in the vicinity of the center point O_{105R} of the subpixel 105R. The vicinity of the center point O_{105R} refers to the possible range of the center point O_{102R} as long as an opening portion of the subpixel 105R is included in the outline of the bottom surface of the lens 102R.

As illustrated in FIG. 3C, the center point O_{102G} of the lens 102G is preferably provided to overlap with a center point O_{105G} of the subpixel 105G. Alternatively, the center point O_{102G} of the lens 102G is preferably provided in the vicinity of the center point O_{105G} of the subpixel 105G. Note that the vicinity of the center point O_{105G} refers to the range where the center point O_{102G} can take in the range where an opening portion of the subpixel 105G is included in the outline of the bottom surface of the lens 102G.

As illustrated in FIG. 3D, the center point O_{102B1} of the lens 102B1 is preferably positioned on a straight line that perpendicularly divides a short side (also referred to as a length w or a distance between long sides) of the subpixel 105B into two parts and is preferably positioned with a distance of r₂ from a center point O_{105B} of the subpixel 105B. The center point O_{102B2} of the lens 102B2 is preferably positioned on a straight line that perpendicularly divides the short side of the subpixel 105B into two parts and is preferably positioned with a distance of r₁ from the center point O_{105B} of the subpixel 105B. Note that deviation of the positions of the center points O_{102B1} and O_{102B2} within the range where the above-described center point O_{102R} or O_{102G} can be positioned can be allowed.

By appropriately setting the pixel size, the lens size, and the lens position in this manner, lenses 102 can be densely arranged over the pixel array as illustrated in FIG. 2B.

Next, results of a simulation where comparison of the front luminance ratio of a display panel including the lenses of one embodiment of the present invention and that of display panels including lenses with other structures is conducted to confirm the effect of the lenses of one embodiment of the present invention are described. Table 1 shows parameters of models used for the simulation. The assumed resolution of the display panel is 5009 ppi with a pixel size of 5.07 μm×5.07 μm.

TABLE 1

| | | | Size in top view | Height | |
|---|---|---|---|---|---|
| | | | [μm] | | Note |
| Subpixel | | 105R | 1.115 × 1.79 | — | Distance between subpixels = 1.09 μm |
| | | 105G | 1.775 × 1.79 | — | |
| | | 105B | 1.1 × 3.98 | — | |
| Lens | M1 to M4 | 102R | 1.1025 (radius of bottom surface r₁) | 1.1025 | Hemispherical lens, common to M1 to M4 |
| | | 102G | 1.4325 (radius of bottom surface r₂) | (r₁) | Spherical lens, common to M1 to M4 |
| | M1 | 102B1 | 1.4325 (radius of bottom surface r₂) | | Spherical lens |
| | | 102B2 | 1.1025 (radius of bottom surface r₁) | | Hemispherical lens |
| | M2 | 102B | 2.205 × 5.07 | | Cylindrical lens |
| | | | | | (Curvature radius of cross section r₁) |
| | M3 | 102B | 2.205 × 5.07 | | M2 + curvature radius r₁ of end portions |
| | M4 | 102B1 | 1.1025 (radius of bottom surface r₁) | | Hemispherical lens |
| | | 102B2 | 1.1025 (radius of bottom surface r₁) | | |

The simulation model of one embodiment of the present invention is a pixel with S-stripe arrangement and is Model M1 where the lens 102R and the lens 102B2 are hemispherical lenses having the same size and the lens 102G and the lens 102B1 are spherical lenses having the same size (see FIG. 2A and FIG. 3A).

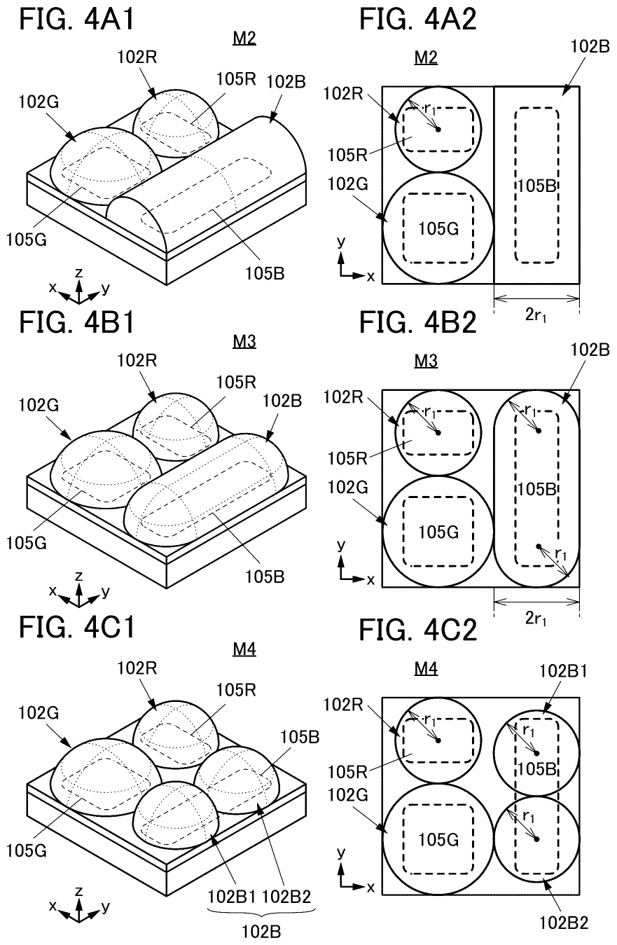

Comparative models are Model M2, Model M3, and Model M4 illustrated in FIGS. 4A1, 4A2, 4B1, 4B2, 4C1, and 4C2. The structures of the subpixels, the lens 102R, and the lens 102G of these models are the same as those of Model M1; however, only the structure of the lens 102B is different among the models.

In Model M2, the lens 102B is a cylindrical lens where the cross section along the short axis is a semicircle with a curvature radius r₁ (equivalent to that of the lens 102R) (see the perspective view of FIG. 4A1 and the top view of FIG. 4A2).

Model M3 has a structure where the lens 102B is a cylindrical lens whose end portions have a curvature radius r₁ unlike the lens 102B in Model M2 (see the perspective view of FIG. 4B1 and the top view of FIG. 4B2).

Model M4 has a structure where the lenses 102B1 and 102B2 are hemispherical lenses having equivalent size unlike the lenses 102B1 and 102B2 in Model M1 (see the perspective view of FIG. 4C1 and the top view of FIG. 4C2).

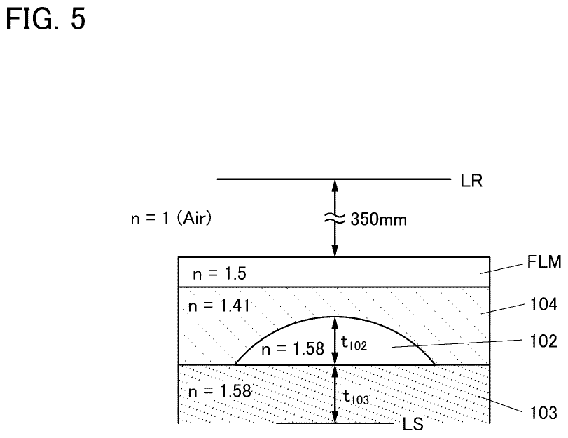

FIG. 5 illustrates a model showing the positional relationship between components used for the calculation and the refractive indices n of the components. The lens 102 is positioned over the light-transmitting insulating layer 103 provided on a light-emitting surface LS of the light-emitting element included in the subpixel. An light-transmitting insulating layer 104 is disposed over the lens 102 and the insulating layer 103. A film FLM is disposed over the insulating layer 104. A light-receiving surface LR is disposed over the film FLM, and it is assumed that there is air between the light-receiving surface LR and the film FLM.

The refractive indices n of the insulating layer 103 and the lens 102 are 1.58, the refractive index n of the insulating layer 104 is 1.41, the refractive index n of the film FLM is 1.5, and the refractive index n of the air is 1. The distance between the top surface of the film FLM and the light-receiving surface LR is 350 mm.

The calculation was performed using illumination analysis simulator LightTools produced by Synopsys, Inc. Assuming that the light source of subpixels is light emission from organic EL elements, an emission spectrum and an alignment pattern in an actual element structure are calculated using an organic EL device simulator Setfos produced by Fluxim AG and the calculation results are utilized.

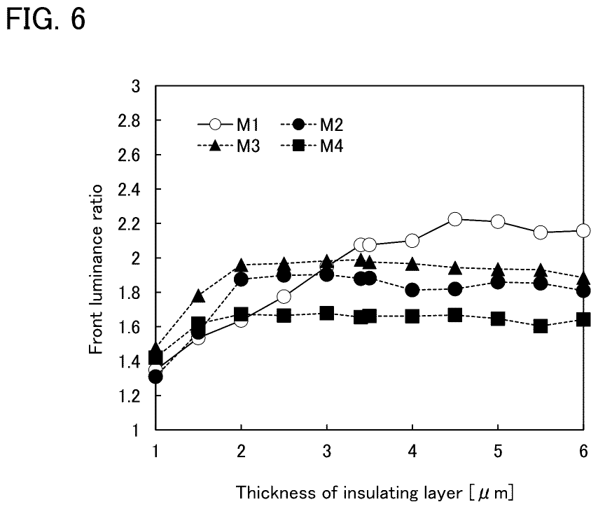

FIG. 6 is a graph of calculation results of the front luminance of the display panels using Model M1 to Model M4, and shows the dependence of the front luminance ratio on the thickness of the insulating layer 103 at the time when the front luminance of the display panel without a lens is set to 1. Note that the luminance in the case where only the subpixel 105B emits light is assumed as the front luminance.

All the models have a front luminance ratio higher than 1 as shown in FIG. 6, which means that provision of a lens over a subpixel is effective as a method for increasing the front luminance. That is, the structures illustrated in FIGS. 4A1, 4A2, 4B1, 4B2, 4C1, and 4C2 used as comparative models are also effective as a method for increasing the front luminance of the display panel. That is, the structures illustrated in FIGS. 4A1 to 4C2 are also regarded as one embodiment of the present invention.

Note that a saturation tendency is observed with respect to the thickness of the insulating layer 103 in all the models. This can be due to two factors. The first factor is that the amount of light directed in the front direction is increased as the thickness of the insulating layer 103 increases and the distance between a lens and the light source becomes closer to the focal length of the lens. The second factor is that the amount of light incident on a lens is reduced as the thickness of the insulating layer 103 and the distance from the light source to the lens are increased.

It is considered that the influence of the first factor is dominant in the range of conditions where the thickness of the insulating layer 103 is relatively small and the front luminance ratio is positively sloped. In addition, it is considered that the influence of the first factor and the influence of the second factor are in balance in the range of the conditions where the thickness of the insulating layer 103 is relatively large and the saturation tendency is shown.

In the simulation results, the magnitude relation of front luminance ratio among the models is Model M4<Model M2<Model M3<Model M1 when the thickness of the insulating layer 103 is greater than or equal to 3.5 μm, which indicates that the structure of one embodiment of the present invention is most preferable.

Model M4 has a structure where two ideal hemispherical lenses are disposed over the subpixel 105B; however, this model is the worst effective. It can be said that this is due to insufficient coverage of the subpixel 105B with the hemispherical lenses and the small bottom areas of the lenses.

Model M2 has a structure where the entire subpixel 105B is covered with a cylindrical lens, and this model is more effective than Model M4. However, it is considered that the effect of a curved surface of the lens only acts in the short axis direction and does not act in the long axis direction along which the lens has no curved surface.

Model M3 has a curved surface in end portions, so that the effect of a curved surface of the lens also appears partly in the long axis direction; thus, Model M2 has higher front luminance than Model M2. However, since regions not including a curved surface of lens still exists in portions other than the end portions in the long axis direction, it can be said that the improvement in the effect from Model M2 is limited.

Model M1 is a variation example of Model M4 and has a structure in which spherical lenses with different radii in the top view (the lens 102B2 is a hemispherical lens) are disposed adjacent to each other over the subpixel 105B. In Model M1, the area of the subpixel 105B covered with lenses can be increased as compared with that of Model M4 and the bottom area of the lenses are increased, so that a larger amount of light from the light-emitting element can enter the lenses; thus, the front luminance can be further increased.

Note that as the thickness of the insulating layer 103 becomes large, the angle dependence of chromaticity variation in white display becomes large in some cases. Thus, the insulating layer 103 preferably has a thickness greater than or equal to 3.5 μm and less than or equal to 6 μm where the front luminance ratio starts to show a saturation tendency; further preferably greater than or equal to 3.5 μm and less than or equal to 5 μm; still further preferably greater than or equal to 3.5 μm and less than or equal to 4.5 μm.

The thickness of the insulating layer 103 at which a saturation tendency of the front luminance ratio is started to be exhibited is larger than those in Models M2 to M4. This is probably because the bottom area of the lenses in Model M1 is larger than that of other models and thus light is easily taken in, and the influence of the second factor described above is inhibited.

Accordingly, it can be said that provision of two spherical lenses over the subpixel 105B sufficiently increases the front luminance ratio of the display panel.

Note that in the structure of Model M1 (the pixel 101a), a region where the subpixel 105B is not covered with the lens is in the vicinity between the lens 102B1 and the lens 102B2. Although the region is small in area, light emitted from the region is less likely to be affected by the effect of the lenses. Thus, it can be said that the front luminance can be further increased when a lens can also be provided over the region.

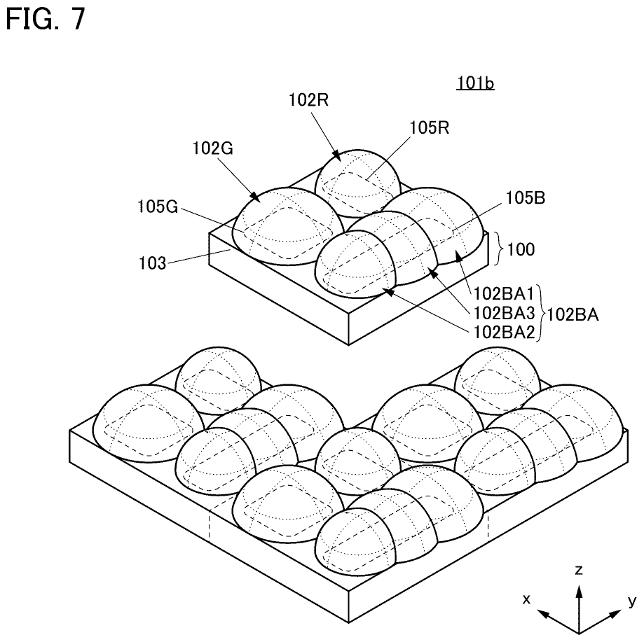

FIG. 7 illustrates a perspective view of a pixel 101b different from the pixel 101a and part of a pixel array including the pixel 101b. The pixel 101b is different from the pixel 101a in that a lens array 102BA is provided over the subpixel 105B. The lens array 102BA has a structure in which a lens is provided also in a region of the subpixel 105B which cannot be covered with the lens 102B in the pixel 101a. The lens array 102BA includes a lens region 102BA1, a lens region 102BA2, and a lens region 102BA3.

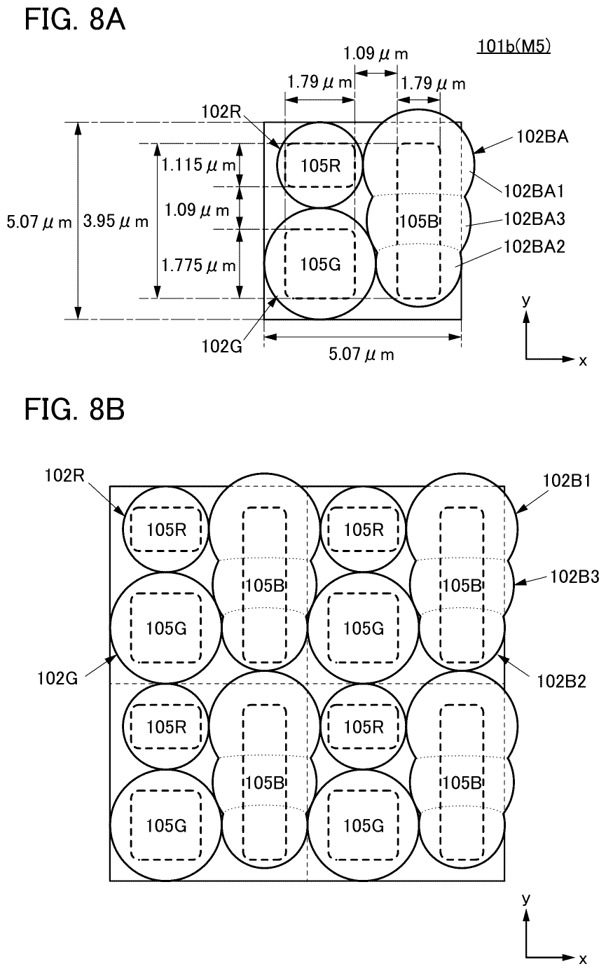

FIG. 8A is an example of a top view of the pixel 101b illustrated in FIG. 7 and illustrates a layout of the pixel 101b that can be used for a display panel with 5009 ppi.

For each of the subpixels 105R and 105G having a low aspect ratio in the top view, a spherical lens that has a circular shape in a top view and covers the subpixel is used, as illustrated in FIG. 8A. The lens array 102BA is used for the subpixel 105B having a high aspect ratio in the top view.

FIG. 8B is an example of a top view illustrating four adjacent pixels 101b that are part of a pixel array. Thus, by selecting an appropriate lens size for each subpixel, the lenses 102R and 102G with circular shapes in a top view and the lens array 102BA can be densely arranged.

Note that although some regions of the lens regions 102BA1 and 102BA3 extend beyond the outline of one pixel 101b as illustrated in FIGS. 8A and 8B, these regions can be positioned in an empty region of an adjacent pixel, and thus the lens regions 102BA1 and 102BA3 can be regarded as being disposed within the occupied area of the pixel 101b substantially.

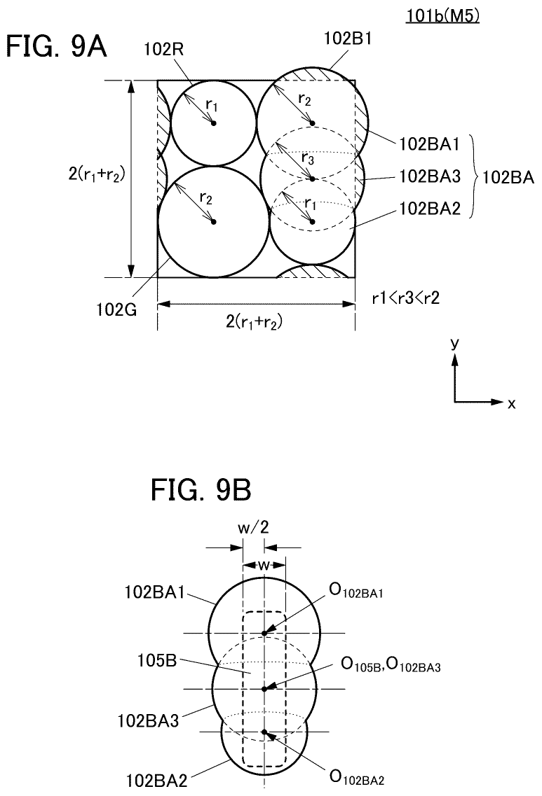

In order to densely arrange the lenses 102R and 102G and the lens array 102BA, when the radius of the bottom surface of the lens 102R is r₁ and the radius of the bottom surface of the lens 102G is r₂ as illustrated in the top view of FIG. 9A, the lens region 102BA1 included in the lens array 102BA includes a region where the radius of the bottom surface is r₂, for example. The lens region 102BA2 includes a region where the radius of the bottom surface is r₁. The lens region 102BA3 includes a region where the radius of the bottom surface is r₃.

The lens region 102BA1 includes a region whose curvature is equal to that of the lens 102B1 in the pixel 101a, and can be regarded as part including the center of the lens 102B1. The position of a center point O_{102BA1} of the lens region 102BA1 is the same as the position of the center point O_{102B1} of the lens 102B1 illustrated in FIG. 3A.

The lens region 102BA2 includes a region whose curvature is equal to that of the lens 102B2 in the pixel 101a, and can be regarded as part including the center of the lens 102B2. The position of a center point O_{102BA2} of the lens region 102BA2 is the same as the position of the center point O_{102B2} of the lens 102B2 illustrated in FIG. 3A.

That is, in the lens array 102BA, a spherical lens having a bottom surface with a radius r₃ is combined with the lenses 102B1 and 102B2 illustrated in FIG. 3A by being provided therebetween.

When the lens region 102BA3 is regarded as part of a spherical lens with a circular shape in the top view, a center point O_{102BA3} thereof is preferably provided on a straight line that perpendicularly divides the short side of the subpixel 105B (also referred to as a length W or the distance between the long sides) and at the position of a center point O_{105B} of the subpixel 105B as illustrated in FIG. 9B. Note that the deviation of the position of the center point O_{102BA3} in the range where the center point O_{102R} or the center point O_{102G} described with reference to FIGS. 3B and 3C can be positioned can be allowed.

In that case, r₃ is preferably as large as possible with the upper limit of the length where the lens 102BA3 is in contact with the lens 102G as illustrated in FIG. 9A. Thus, relation between the radii of the lens regions 102BA1 to 102BA3 is r₁<r₃<r₂, and the relation between curvatures is the lens region 102BA2<the lens region 102BA3<the lens region 102BA1.

With such a structure, the bottom area of the lens array 102BA can be increased, and the amount of light incident on the lens array 102BA from the light-emitting element can be increased, so that the front luminance can be further increased.

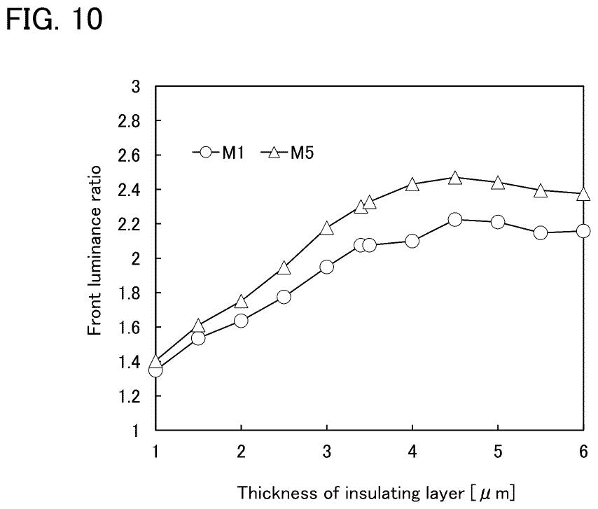

FIG. 10 shows the simulation results of the front luminance of a display panel using the pixel 101b illustrated in FIG. 7, FIGS. 8A and 8B, and FIGS. 9A and 9B as Model M5, which are compared with those of Model M1.

As shown in FIG. 10, it is confirmed that Model M5 can have higher front luminance than Model M1 by using the lens array 102BA covering the entire subpixel 105B. Note that the front luminance ratio tends to be saturated at a thickness of the insulating layer 103 of 4 μm or more. Thus, it can be said that the thickness of the insulating layer 103 in consideration of chromaticity variation is preferably greater than or equal to 4 μm and less than or equal to 6 μm, further preferably greater than or equal to 4 μm and less than or equal to 5 μm, still further preferably greater than or equal to 4 μm and less than or equal to 4.5 μm.

As described above, over the subpixel with a relatively high aspect ratio, two spherical lenses with circular shapes in a top view are disposed to be adjacent to each other, whereby light from the light-emitting element can be efficiently directed in the front direction and the light extraction efficiency of the display apparatus can be increased.

Alternatively, over the subpixel with a relatively high aspect ratio, a lens array where a first lens region, a second lens region, and a third lens region with different curvatures are arranged in one direction in this order, whereby light from the light-emitting element can be efficiently directed in the front direction and the light extraction efficiency of the display apparatus can be increased.

Thus, with the use of one embodiment of the present invention, a voltage applied to the light-emitting element can be reduced, so that the reliability of the light-emitting element can be increased and the power consumption of the light-emitting element can be reduced.

The light-emitting element that can be used in one embodiment of the present invention preferably has a metal maskless (MML) structure in which light-emitting layers are separately formed by a lithography process without using a fine metal mask (FMM). A light-emitting element having an MML structure can have a high aperture ratio and emit light with high luminance or low power consumption as compared with a light-emitting element manufactured using an FMM. One embodiment of the present invention is a structure in which a light-emitting element with an MML structure and a convex lens are combined to further increase light extraction efficiency.

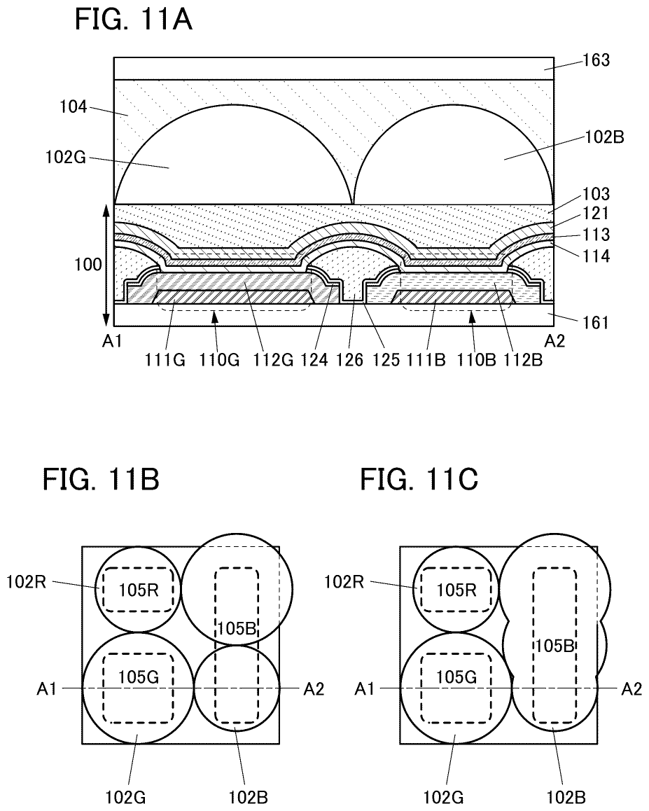

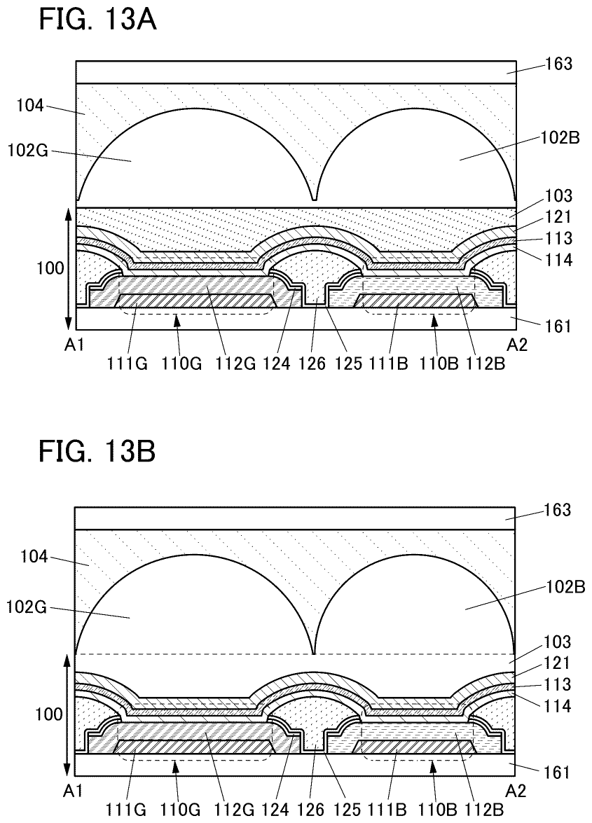

FIG. 11A is a diagram corresponding to a cross section of the pixel 101a along A1-A2 illustrated in FIG. 11B or a cross section of the pixel 101b along A1-A2 illustrated in FIG. 11C. Note that although the lens 102B is illustrated in FIG. 11A and FIGS. 13A and 13B, the lens 102B can be replaced with the lens array 102BA.

The pixel 101a and the pixel 101b each include the subpixel 105R, the subpixel 105G, and the subpixel 105B; however, here, the description of the subpixel 105R is omitted and the subpixel 105G and the subpixel 105B are described. For the subpixel 105R, the description of the subpixel 105G and the subpixel 105B can be referred to.

A light-emitting element 110G included in the subpixel 105G and a light-emitting element 110B included in the subpixel 105B are provided over a substrate 161. The substrate 161 includes a component such as a pixel circuit in addition to a support.

As each of the light-emitting elements 110G and 110B, an organic light-emitting diode (OLED) or a quantum-dot light-emitting diode (QLED) is preferably used, for example. Examples of the light-emitting substance contained in the EL element include not only organic compounds but also inorganic compounds (e.g., quantum dot materials).

The light-emitting element 110G includes a pixel electrode 111G, an organic layer 112G, a common layer 114, and a common electrode 113. The light-emitting element 110B includes a pixel electrode 111B, an organic layer 112B, the common layer 114, and the common electrode 113. The common layer 114 and the common electrode 113 are shared by the light-emitting elements 110G and 110B.

The organic layer 112G of the light-emitting element 110G contains at least a light-emitting organic compound that emits green light. The organic layer 112B of the light-emitting element 110B contains at least a light-emitting organic compound that emits blue light. Each of the organic layers 112G and 112B can also be referred to as an EL layer, and includes at least a layer containing a light-emitting substance (a light-emitting layer).

Hereafter, the term “light-emitting element 110” is sometimes used to describe matters common to the light-emitting elements 110G and 110B. Likewise, in the description of matters common to the components that are distinguished using alphabets, such as the organic layers 112G and 112B, reference numerals without such alphabets are sometimes used.

The organic layer 112 and the common layer 114 can each independently include one or more of an electron-injection layer, an electron-transport layer, a hole-injection layer, and a hole-transport layer. For example, the organic layer 112 can include a hole-injection layer, a hole-transport layer, a light-emitting layer, and an electron-transport layer that are stacked from the pixel electrode 111 side, and the common layer 114 can include an electron-injection layer.

The pixel electrode 111G and the pixel electrode 111B are provided for the respective light-emitting elements. Each of the common electrode 113 and the common layer 114 is provided as a continuous layer shared by the light-emitting elements. A conductive film that has a property of transmitting visible light is used for either the pixel electrodes or the common electrode 113, and a reflective conductive film is used for the other. When the pixel electrodes are light-transmitting electrodes and the common electrode 113 is a reflective electrode, a bottom-emission display apparatus is obtained. Meanwhile, when the pixel electrodes are reflective electrodes and the common electrode 113 is a light-transmitting electrode, a top-emission display apparatus is obtained. Note that when both the pixel electrodes and the common electrode 113 have a property of transmitting light, a dual-emission display apparatus is obtained.

A protective layer 121 is provided over the common electrode 113 so as to cover the light-emitting elements 110G and 110B. The protective layer 121 has a function of preventing diffusion of impurities such as water into the light-emitting elements from above.

The pixel electrode 111 preferably has an end portion with a tapered shape. In the case where the pixel electrode 111 has an end portion with a tapered shape, the organic layer 112 that is provided along the end portion of the pixel electrode 111 can also have an inclined shape. When the end portion of the pixel electrode 111 has a tapered shape, coverage with the organic layer 112 provided to cover the end portion of the pixel electrode 111 can be improved. The side surface of the pixel electrode 111 having such a tapered shape is preferable because it allows a foreign matter (such as dust or particles) mixing during the manufacturing process to be easily removed by treatment such as cleaning.

In this specification and the like, a tapered shape indicates a shape in which at least part of a side surface of a structure is inclined to a substrate surface. For example, a tapered shape preferably includes a region where the angle formed between the inclined side surface and the substrate surface (such an angle is also referred to as a taper angle) is less than 90°.

The organic layer 112 is processed into an island shape using a resist mask formed by a lithography method, for example. Thus, the angle formed between the top surface and a side surface of an end portion of the organic layer 112 is approximately 90°. By contrast, an organic film formed using a fine metal mask (FMM) or the like has a thickness that tends to gradually decrease with decreasing distance to an end portion, and has a top surface forming a slope in an area extending greater than or equal to 1 μm and less than or equal to 10 μm from the end portion, for example; thus, such an organic film has a shape whose top surface and side surface cannot be easily distinguished from each other.

An insulating layer 124, an insulating layer 125, and a resin layer 126 are included between two adjacent light-emitting elements.

Between two adjacent light-emitting elements, a side surface of the organic layer 112 of one light-emitting element faces a side surface of the organic layer 112 of the other light-emitting element with the resin layer 126 therebetween. The resin layer 126 is positioned between two adjacent light-emitting elements so as to fill the region between the end portions of their organic layers 112 and the region between the two organic layers 112. The resin layer 126 has a top surface with a smooth convex shape. The top surface of the resin layer 126 is covered with the common layer 114 and the common electrode 113.

The resin layer 126 functions as a planarization film that fills a step between two adjacent light-emitting elements. Providing the resin layer 126 can prevent a phenomenon in which the common electrode 113 is divided by a step at an end portion of the organic layer 112 (also referred to as disconnection) from occurring and the common electrode over the organic layer 112 from being insulated.

The organic layers 112 included in the adjacent light-emitting elements 110 are insulated from each other by the resin layer 126. Accordingly, a leakage current through the organic layers 112 between the adjacent light-emitting elements can be reduced, so that unnecessary light emission due to crosstalk can be inhibited.

An insulating layer containing an organic material can be suitably used as the resin layer 126. Examples of materials used for the resin layer 126 include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. The resin layer 126 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin.

A photosensitive resin can also be used for the resin layer 126. A photoresist may be used for the photosensitive resin. As the photosensitive resin, a positive photosensitive material or a negative photosensitive material can be used.

The resin layer 126 may contain a material absorbing visible light. For example, the resin layer 126 itself may be made of a material absorbing visible light, or the resin layer 126 may contain a pigment absorbing visible light. For example, the resin layer 126 can be formed using a resin that can be used as a color filter that transmits red, blue, or green light and absorbs light of the other colors; or a resin that contains carbon black as a pigment and functions as a black matrix.

When the resin layer 126 absorbs light emitted from the light-emitting element in an oblique direction, light leakage (stray light) from the light-emitting element to the adjacent light-emitting element through the resin layer 126 can be inhibited. Thus, the display quality of the display apparatus can be improved. Since no polarizing plate is required to improve the display quality of the display apparatus, the weight and thickness of the display apparatus can be reduced.

The insulating layer 125 is provided in contact with the side surface of the organic layer 112. Moreover, the insulating layer 125 is provided to cover a top end portion of the organic layer 112. Part of the insulating layer 125 is in contact with the top surface of the substrate 161.

The insulating layer 125 is positioned between the resin layer 126 and the organic layer 112 to function as a protective film for preventing contact between the resin layer 126 and the organic layer 112. In the case of bringing the resin layer 126 into contact with the organic layer 112, the organic layer 112 might be dissolved by an organic solvent or the like used in formation of the resin layer 126. In view of this, the insulating layer 125 is provided between the organic layer 112 and the resin layer 126 to protect the side surface of the organic layer 112.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon nitride film or a silicon oxide film that is formed by an ALD method is used for the insulating layer 125, the insulating layer 125 has a small number of pin holes and excels in a function of protecting the EL layer.

Note that in this specification and the like, an oxynitride refers to a material that contains more oxygen than nitrogen, and a nitride oxide refers to a material that contains more nitrogen than oxygen. For example, silicon oxynitride refers to a material that contains more oxygen than nitrogen, and silicon nitride oxide refers to a material that contains more nitrogen than oxygen.

The insulating layer 125 can be formed by a sputtering method, a CVD method, a PLD method, an ALD method, or the like. The insulating layer 125 is preferably formed by an ALD method achieving good coverage.

Between the insulating layer 125 and the resin layer 126, a reflective film (e.g., a metal film containing one or more of silver, palladium, copper, titanium, aluminum, and the like) may be provided to reflect light that is directed from the light-emitting layer. In this case, the light extraction efficiency can be increased.

Part of a protective layer (also referred to as a mask layer or a sacrificial layer) for protecting the organic layer 112 during etching of the organic layer 112 survives the etching to become the insulating layer 124. For the insulating layer 124, the material that can be used for the insulating layer 125 can be used. In particular, the insulating layer 124 and the insulating layer 125 are preferably formed using the same material, in which case an apparatus or the like for processing can be used in common.

In particular, a metal oxide film such as an aluminum oxide film or a hafnium oxide film or an inorganic insulating film such as a silicon nitride film or a silicon oxide film that is formed by an ALD method have a small number of pinholes, and thus excel in the function of protecting the EL layer and are preferably used for the insulating layer 125 and the insulating layer 124.

The protective layer 121 can have, for example, a single-layer structure or a stacked-layer structure at least including an inorganic insulating film. Examples of the inorganic insulating film include oxide films and nitride films such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

The insulating layer 103 is provided over the protective layer 121. For the insulating layer 103, an organic material that can be used for the resin layer 126 can be used, for example. The formation of the insulating layer 103 can reduce the influence of an uneven shape due to components below, so that a component such as a lens array can be easily formed. Note that the substrate 161 and the components thereover up to the insulating layer 103 correspond to the stack 100 illustrated in FIG. 1.

A plano-convex lens 102 (lenses 102G and 102B) is provided over the insulating layer 103 so as to overlap with the light-emitting element 110. The insulating layer 104 is provided over the lens 102. The lens 102 and the light-emitting element 110 are provided as a pair. In other words, one lens 102 is provided for one subpixel.

The lens 102 is provided above the light-emitting element 110 (in the direction in which light is directed). Since light emitted from the light-emitting element 110 spreads in a certain extent, light not extracted to the outside of the display apparatus is lost. Thus, it is preferable to increase the front luminance of the display apparatus. Since the lens 102 has a convex shape, the lens 102 can lead light to be converged. That is, divergence of the light emitted from the light-emitting element can be inhibited, so that the light extraction efficiency of the display apparatus can be increased. The lens 102 can be formed using a material similar to that for the resin layer 126 in a similar step.

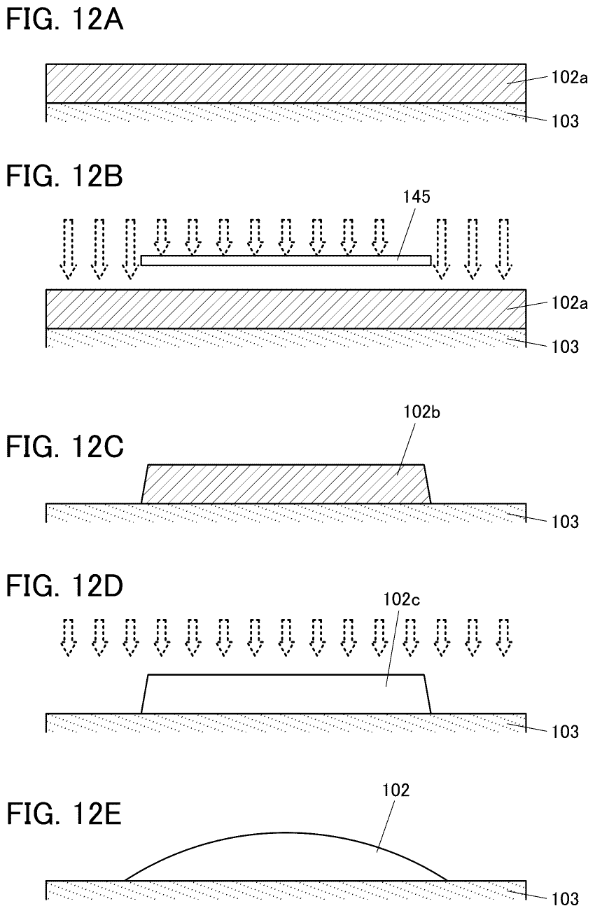

FIGS. 12A, 12B, 12C, 12D, and 12E are diagrams illustrating a manufacturing process of the lens 102 formed over the insulating layer 103.

First, a photosensitive resin is applied onto the insulating layer 103 and prebaking is performed, so that a resin layer 102a is formed (see FIG. 12A). As the photosensitive resin, for example, a material for forming the resin layer 126 described in Embodiment 1 can be used. Although an example in which a positive photosensitive resin is used is described here, a negative photosensitive resin may be used.

Next, a photomask 145 is used to shield a region where the lens 102 is to be formed from light and perform light exposure on the resin layer 102a (see FIG. 12B). In the case where a negative photosensitive resin is used, a photomask that shield a region where the lens 102 is not to be formed from light is used.

Then, an unnecessary region of the resin layer 102a is removed by a development process, so that a resin layer 102b is formed (see FIG. 12C). Here, since the resin layer 102b is not exposed to light, an unreacted component remains in the resin layer 102b, and the resin layer 102b is colored in some cases. The lens 102 to be formed preferably has a high visible-light transmittance; thus, in the case where the resin layer 102b is colored, the resin layer 102b is exposed to light to promote a reaction.

By promoting the reaction, a resin layer 102c having an improved transmittance can be formed (see FIG. 12D). Performing such light exposure after the development process can decrease post-baking temperature of the resin layer 102c in a later process in some cases. Note that in the case where the resin layer 102b is not colored, the light exposure after the development process may be omitted.

Then, post-baking is performed to reflow and harden the resin layer 102c, so that the lens 102 including a spherical surface is formed (FIG. 12E).

Note that in the case of manufacturing the lens array 102BA included in the pixel 101b, the amount of light exposure is adjusted for each part of the resin layer 102b in the step in FIG. 12C. For example, with the use of a multi-tone mask such as a half-tone mask or a gray-tone mask, an island-shaped lens array with a plurality of curvatures can be formed without dividing one island-shaped resin layer 102b.

The insulating layer 104 provided over the lens 102 is an adhesive layer provided between the lens 102 and the substrate 163 and is preferably formed using an organic material. For example, an optical adhesive or the like having a refractive index close to that of the glass or the film that can be used for the substrate 163 can be used.

The above is the description of the structure examples of the light-emitting elements and the vicinity thereof.

Although FIG. 11A illustrates an example in which the lens 102G and the lens 102B have substantially the same height, one embodiment of the present invention is not limited thereto. For example, the lens 102G and the lens 102B may have different heights. The shape of the subpixel in the top view may vary depending on the emission color, and each lens needs to have a shape appropriate for light emitted from the corresponding subpixel.

As illustrated in FIG. 13A, the lenses 102G and 102B may be bonded to each other in the vicinity of end portions. In terms of prevention of color mixture, adjacent lenses are preferably separated; however, bonding of adjacent lenses results in an increase in width of the lens as a whole, so that the amount of light incident on the lens 102 from the light-emitting element 110 can be increased. Thus, the light extraction efficiency of the display panel can be increased in some cases. Note that the height of the bonding portion of the lenses is preferably as low as possible to inhibit color mixture.

As illustrated in FIG. 13B, the insulating layer 103 and the lens 102 may be formed using materials with the same refractive index. For example, when the insulating layer 103 and the lens 102 are formed using the same resin material, the adhesion at the interface therebetween can be increased. Furthermore, the use of the same material, the common use of manufacturing equipment, and the like can reduce the manufacturing cost.

Note that in the structure illustrated in FIG. 11A, the refractive indices of the insulating layer 104, the lens 102, and the insulating layer 103 that serve as a path of light emitted from the light-emitting element 110 may be low in this order. For light going straight without refraction, the refractive index difference of each interface can be reduced by setting refractive index difference of interfaces such that the refractive indices decrease gradually as the light travels in the traveling direction, whereby the reflection at interfaces can be reduced. Accordingly, it can be said that the extraction efficiency of light going straight can be improved. This effect can be derived from Fresnel equations.

Note that the structures in FIG. 11A and FIGS. 13A and 13B can be combined as appropriate.

The light extraction efficiency of the display panel can be increased by providing the lens of one embodiment of the present invention over the light-emitting element as described above. It is also effective to use a light-emitting element with higher emission efficiency to increase the front luminance of the display panel. In principle, the luminance of a tandem organic EL element is increased as the number of units stacked increases as long as the current density is the same. The luminance of a two-unit tandem organic EL element can be twice that of a single organic EL element.

Since the lifetime of an organic EL element depends on the current density, the lifetime of a tandem organic EL element is equivalent to that of a single organic EL element in the same current density even though the luminance of the tandem organic EL element is twice as high as that of the single organic EL element. That is, a tandem organic EL element can be regarded as being effective in increasing the luminance and the reliability of an organic EL element.

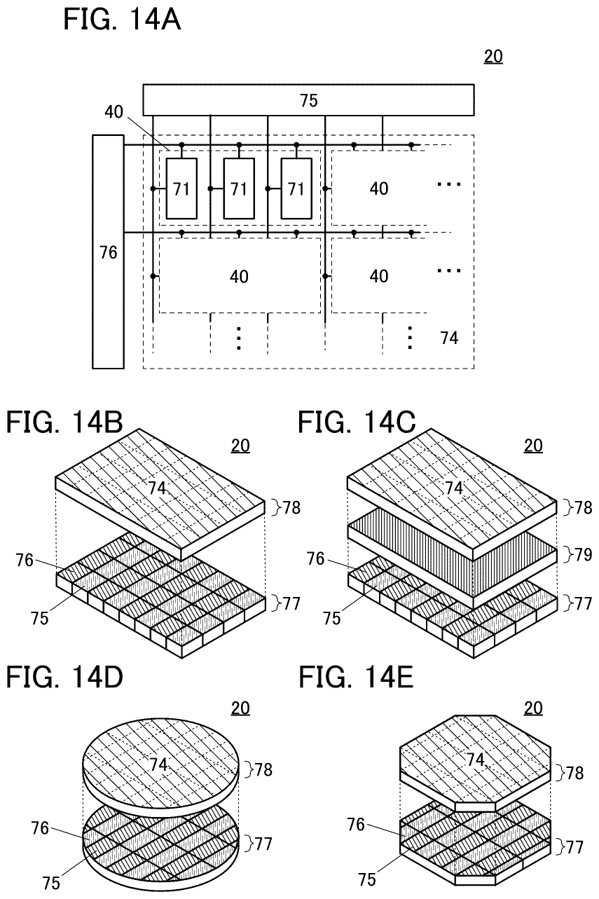

FIG. 14A is a block diagram illustrating the display apparatus of one embodiment of the present invention. A display apparatus 20 includes a pixel array 74, a circuit 75, and a circuit 76. The pixel array 74 includes pixels 40 arranged in a column direction and a row direction.

The pixel 40 can include a plurality of subpixels 71. The subpixel 71 has a function of emitting light for display. When colors of R (red), G (green), B (blue), and the like are assigned to light emitted from the subpixels 71, full-color display can be performed.

The subpixel 71 includes a light-emitting device that emits unpolarized visible light. As the light-emitting device, an EL element such as an organic light-emitting diode (OLED) or a quantum-dot light-emitting diode (QLED) is preferably used. Examples of a light-emitting substance contained in the EL element include a substance exhibiting fluorescence (a fluorescent material), a substance exhibiting phosphorescence (a phosphorescent material), a substance exhibiting thermally activated delayed fluorescence (a thermally activated delayed fluorescent (TADF) material), and an inorganic compound (e.g., a quantum dot material). An LED such as a micro-LED can also be used as the light-emitting device.

The circuit 75 and the circuit 76 are driver circuits for driving the subpixel 71. The circuit 75 can have a function of a source driver circuit and the circuit 76 can have a function of a gate driver circuit. A shift register circuit or the like can be used as the circuit 75 and the circuit 76, for example.

Note that the display apparatus 20 may be divided into a plurality of regions horizontally and vertically, and pixels may be driven for each divided region.

For example, as illustrated in FIG. 14B, each of the circuit 75 and the circuit 76 can be divided and arranged under the pixel array 74. In this case, the display apparatus 20 has a stacked-layer structure of a layer 77 and a layer 78, a plurality of the circuits 75 and a plurality of the circuits 76 are provided in the layer 77, and the pixel array 74 is provided in the layer 78 to overlap with the circuits 75 and 76.

When each of the circuit 75 and the circuit 76 is divided and arranged, the pixel array 74 can be driven for each divided region. For example, operating parts of the pixel array 74 at different frame rates is possible. Display with different resolution for each part of the pixel array 74 is possible, and thus the pixel array 74 can be used for foveated rendering.

Since the driver circuits are provided below the pixel array 74, the wiring length can be shortened and the wiring capacitance can be reduced. Accordingly, a display apparatus capable of high-speed operation with low power consumption can be provided. In addition, the display apparatus 20 can have a narrow bezel.

The layouts and areas of the circuit 75 and the circuit 76 illustrated in FIG. 14B are examples, and can be changed as appropriate. Some parts of the circuit 75 and the circuit 76 can be provided in the same layer as the pixel array 74. Circuits such as a memory circuit, an arithmetic circuit, and a communication circuit may be provided in the layer 77.

In this structure, for example, the layer 77 can be provided on single crystal silicon substrate, the circuit 75 and the circuit 76 can be formed with transistors containing silicon in channel formation regions (hereinafter referred to as Si transistors), and pixel circuits included in the pixel array 74 provided in the layer 78 can be formed with transistors containing a metal oxide in channel formation regions (hereinafter referred to as OS transistors). An OS transistor can be formed using a thin film and can be stacked over a Si transistor.

Note that a structure illustrated in FIG. 14C in which a layer 79 including OS transistors is provided between the layer 77 and the layer 78 may be employed. The layer 79 can be provided with OS transistors composed of some of the pixel circuits included in the pixel array 74. Alternatively, OS transistors composed of some of the circuits 75 and 76 is provided in the layer 79. Alternatively, OS transistors composed of some of the circuits that can be provided in the layer 77, such as a memory circuit, an arithmetic circuit, and a communication circuit, can be provided in the layer 79.

The shape of the display apparatus 20 in the top view is not limited to a rectangle and may be a circle as illustrated in FIG. 14D. Alternatively, polygons such as octagons illustrated in FIG. 14E may be employed.

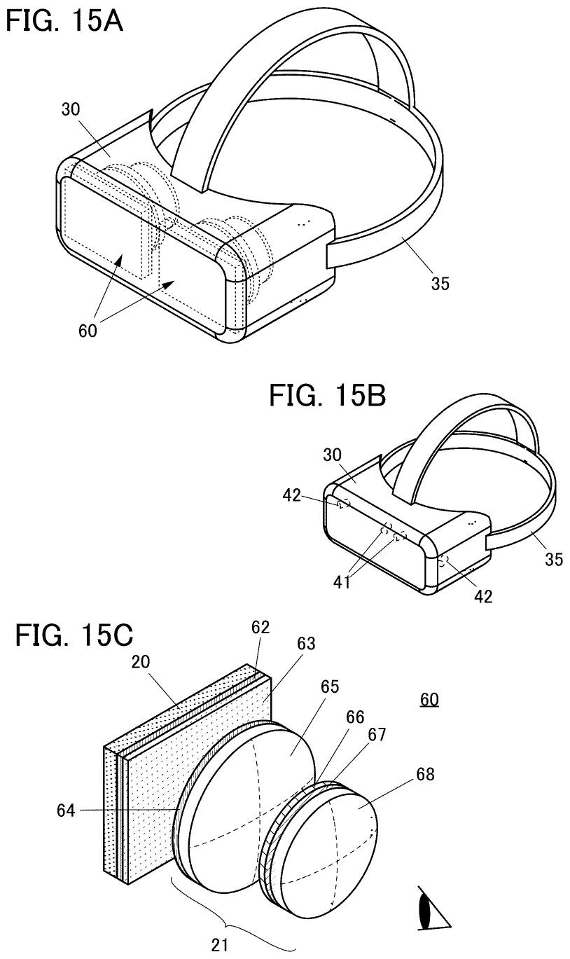

FIG. 15A is a diagram illustrating an example of a glasses-type device including the display apparatus of one embodiment of the present invention and an optical device. Here, a combination of the display apparatus 20 and an optical device 21 is denoted by dashed lines as a display unit 60. FIG. 15C illustrates components of the display unit 60.

A user can see images displayed on the display apparatus 20 by bringing his/her eyes closer to the vicinity of the optical device 21 provided on the display surface side of the display apparatus 20. The user recognizes the image while the viewing angle is widened by the optical device 21, and thus can obtain sense of immersion and a realistic sensation.

A linear polarizing plate 62 and a retardation plate 63 can be attached to the display surface of the display apparatus 20. The optical device 21 can include a half mirror 64, a lens 65, a retardation plate 66, a reflective polarizing plate 67, and a lens 68, for example.

The optical device 21 converts light emitted from the display apparatus 20 into linearly polarized light or circularly polarized light and utilizes, thereby selectively performing reflection and transmission with a component disposed on an optical path. Thus, the optical path length can be ensured in a limited space, whereby the focal length of the optical device can be shortened. Such an optical system is referred to as a catadioptric system. It is also called a pancake lens in some cases because of its thin shape.

The two display units 60 are incorporated in a housing 30 such that surfaces of the lenses 68 are exposed on the inner side. One of the display units 60 is for a right eye, the other is for a left eye, and each of the display units 60 displays an image using parallax, whereby a user can sense the three-dimensionality of the image.

The housing 30 or a support 35 may be provided with an input terminal and an output terminal. To the input terminal, a cable for supplying a video signal from a video output device or the like, power for charging the battery, and the like can be connected. The output terminal can function as, for example, an audio output terminal to which earphones, headphones, or the like can be connected. Note that in the case where audio data can be output by wireless communication or sound is output from an external video output device, the audio output terminal is not necessarily provided.

A wireless communication module, a memory module, and the like may be provided inside the housing 30 or the support 35. A content to be watched can be downloaded via wireless communication using the wireless communication module and stored in the memory module. In this manner, the user can watch the downloaded content offline.

As illustrated in FIG. 15B, a sight line sensor 41 may be provided in the housing 30. The sight line sensor 41 uses light emitted from a light source 42 provided in the housing 30 and detects the gaze by reading a change of reflected light due to the movement of the iris. As the light emitted from the light source 42, near-infrared light with extremely low luminosity is preferably used. For example, operation buttons for power-on, power-off, sleep, volume control, channel change, menu display, selection, decision, and back, and operation buttons for play, stop, pause, fast forward, and rewinding of moving images are displayed and visually recognized, whereby the respective operations can be performed. The user's fatigue level may be detected from the number of blinks or the like and an alert may be displayed, for example.

With use of the display apparatus of one embodiment of the present invention for the glasses-type device, an electronic device with low power consumption and high reliability is achieved.

At least part of this embodiment can be implemented in combination with the other embodiment described in this specification as appropriate.

### Embodiment 2

In this embodiment, structure examples of display panels which can be used for a display apparatus of one embodiment of the present invention will be described.

The display panel of this embodiment has high resolution. Specifically, the display panel is suitably used for display portions of devices for VR such as a head-mounted display, glasses-type devices capable of being worn on a head such as a glasses-type device for AR, or wearable devices.

### [Display Module]

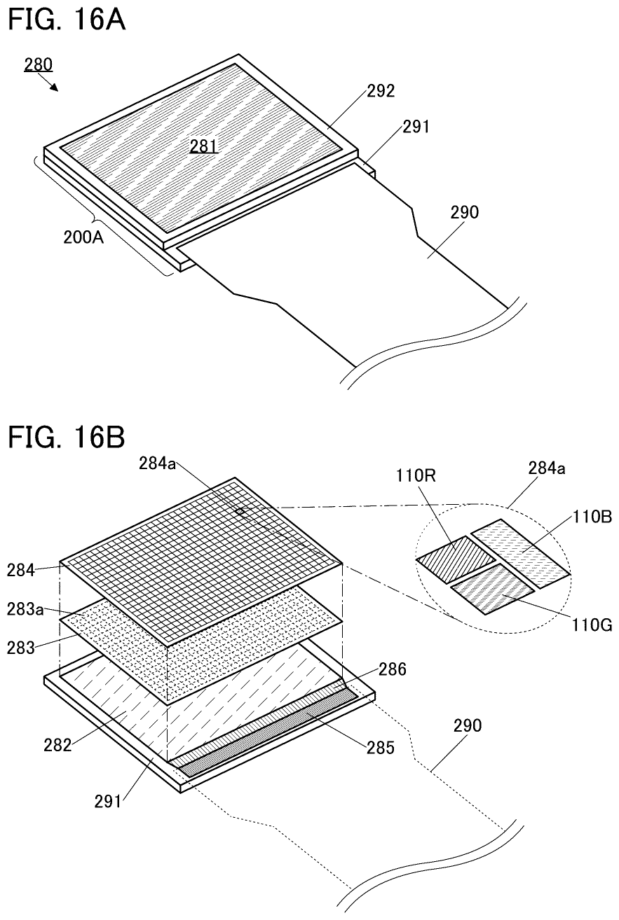

FIG. 16A is a perspective view of a display module 280. The display module 280 includes a display panel 200A and an FPC 290. Note that the display panel included in the display module 280 is not limited to the display panel 200A and may be any of display panels 200B to 200F to be described later.

The display module 280 includes a substrate 291 and a substrate 292. The display module 280 includes a display portion 281. The display portion 281 is a region where an image is displayed.

FIG. 16B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are connected to each other through a wiring portion 286 formed of a plurality of wirings.

The pixel portion 284 includes a plurality of pixels 284a arranged periodically. An enlarged view of one pixel 284a is illustrated on the right side in FIG. 16B. The pixel 284a includes a light-emitting element 110R emitting red light, the light-emitting element 110G emitting green light, and the light-emitting element 110B emitting blue light.

The pixel circuit portion 283 includes a plurality of pixel circuits 283a arranged periodically. One pixel circuit 283a controls light emission from three light-emitting devices included in one pixel 284a. One pixel circuit 283a may include three circuits each of which controls light emission from one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. Thus, an active matrix display panel is achieved.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like. A transistor included in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have significantly high pixel density. For example, the pixels 284a are preferably arranged in the display portion 281 with a pixel density higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a device for VR such as a head-mounted display or a glasses-type device for AR. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic devices including a relatively small display portion. For example, the display module 280 can be suitably used in a display portion of a wearable electronic device, such as a wrist watch.

### [Display Panel 200A]

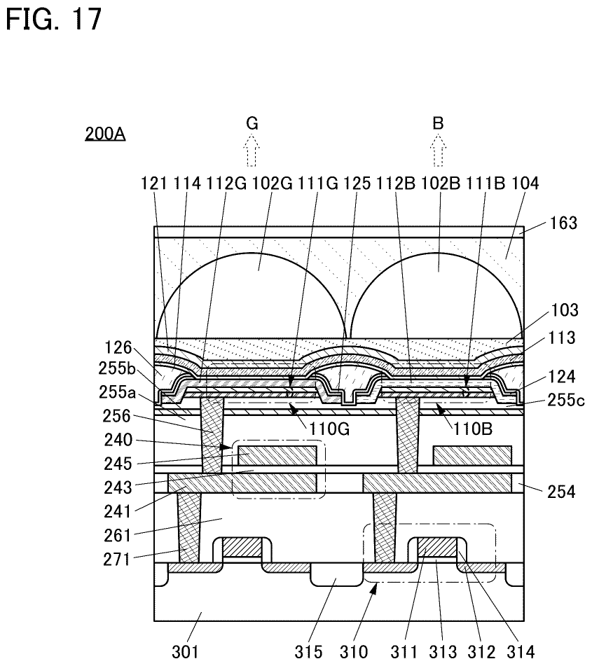

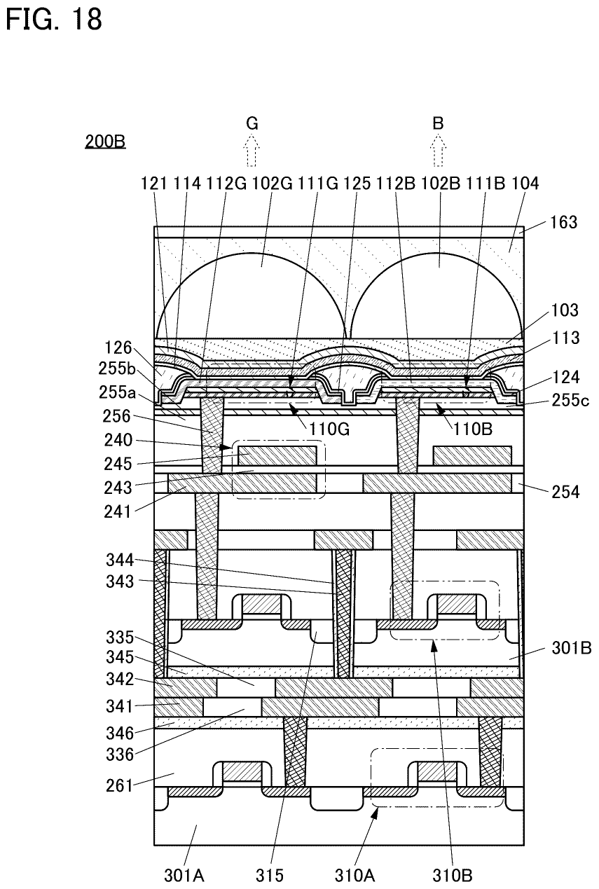

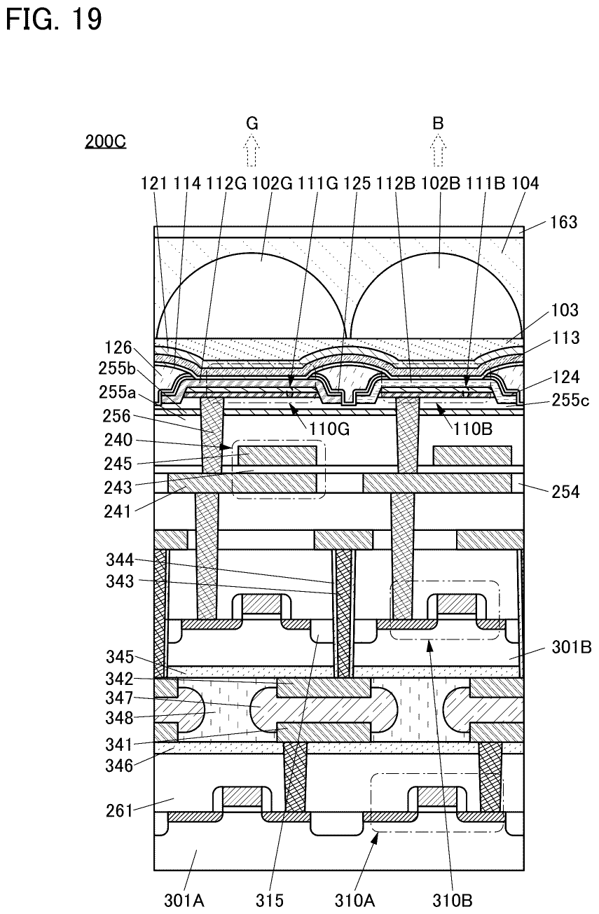

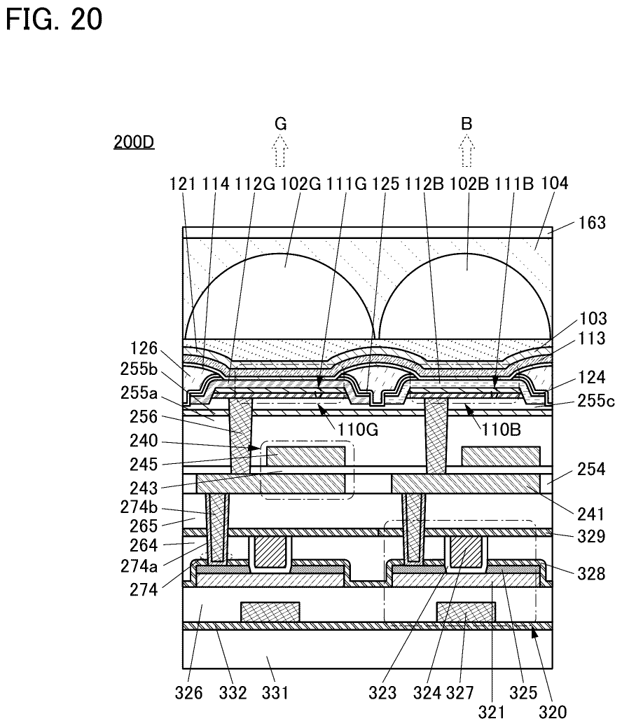

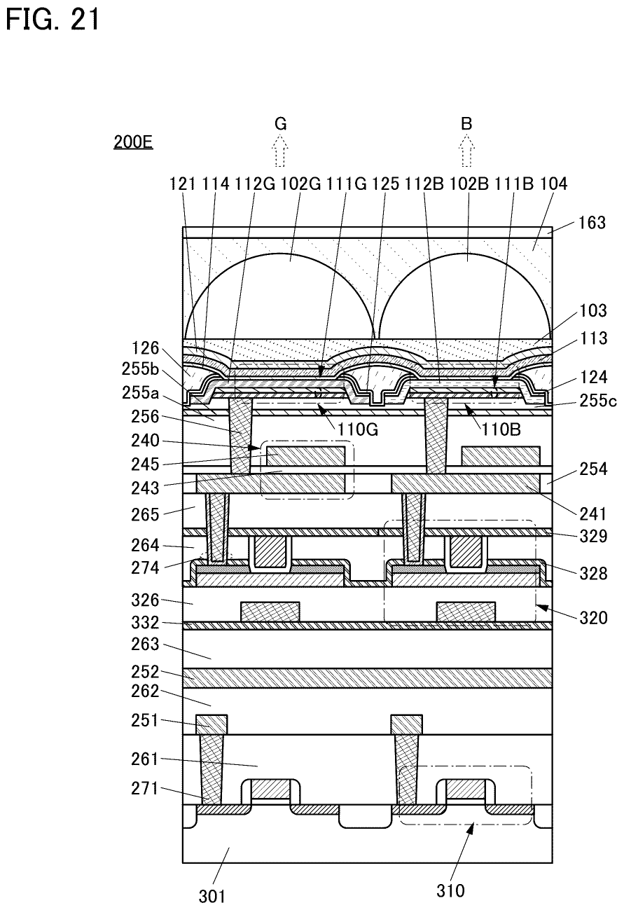

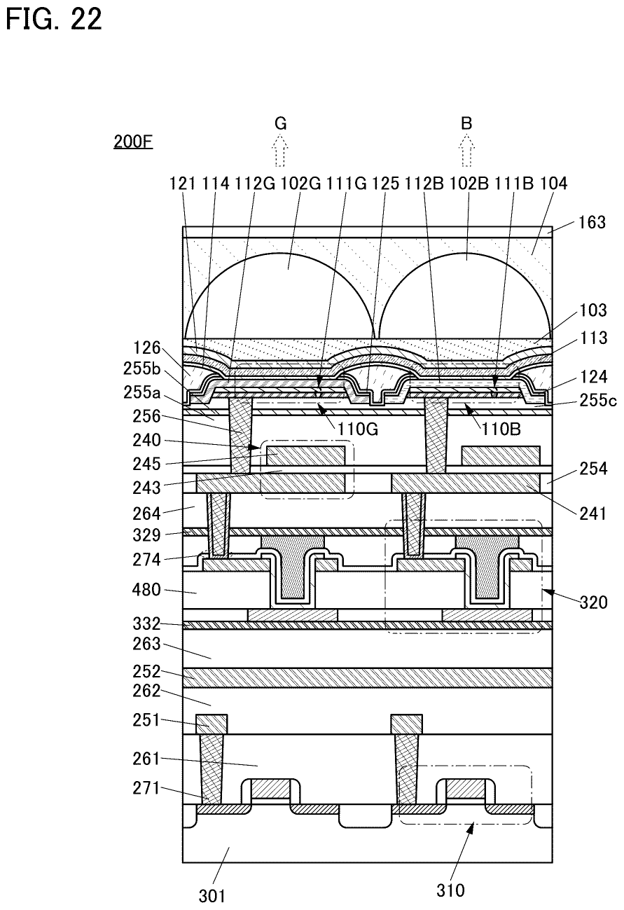

The display panel 200A illustrated in FIG. 17 includes a substrate 301, the light-emitting elements, a capacitor 240, and a transistor 310. Note that in FIG. 17, FIG. 18, FIG. 19, FIG. 20, FIG. 21, and FIG. 22, an example in which the light-emitting element 110G that emits green light and the light-emitting element 110B that emits blue light are included as the light-emitting elements is illustrated.

The substrate 301 corresponds to the substrate 291 in FIGS. 16A and 16B.

The transistor 310 includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is connected to one of a source and a drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, an insulating layer 255b is provided over the insulating layer 255a, and an insulating layer 255c is provided over the insulating layer 255b.

An inorganic insulating film can be suitably used as each of the insulating layers 255a, 255b, and 255c. For example, it is preferable that a silicon oxide film be used as the insulating layers 255a and 255c and a silicon nitride film be used as the insulating layer 255b. This enables the insulating layer 255b to function as an etching protective film. Although this embodiment describes an example where the insulating layer 255c is partly etched and a depressed portion is formed, the depressed portion is not necessarily provided in the insulating layer 255c.

The light-emitting element 110G and the light-emitting element 110B are provided over the insulating layer 255c. Embodiment 1 can be referred to for the structures of the light-emitting element 110G and the light-emitting element 110B.

In the display panel 200A, since the light-emitting devices of different colors are separately formed, the difference between the chromaticity at low luminance emission and that at high luminance emission is small. Furthermore, since the organic layers 112G and 112B are separated from each other, crosstalk generated between adjacent subpixels can be inhibited while the display panel has high resolution. Accordingly, the display panel can have high resolution and high display quality.

In the region between adjacent light-emitting elements, the insulating layer 125 and the resin layer 126 are provided.

The pixel electrodes 111G and 111B are each connected to one of the source and the drain of the transistor 310 through a plug 256 embedded in the insulating layers 255a, 255b, and 255c, the conductive layer 241 embedded in the insulating layer 254, and the plug 271 embedded in the insulating layer 261. The top surface of the insulating layer 255c and the top surface of the plug 256 are level with or substantially level with each other. Any of a variety of conductive materials can be used for the plugs.

The protective layer 121 is provided over the light-emitting elements 110G and 110B. The substrate 163 is attached over the protective layer 121 with the insulating layer 104 functioning as an adhesive layer.

An insulating layer covering an end portion of the top surface of the pixel electrode 111 is not provided between two adjacent pixel electrodes 111. Thus, the distance between adjacent light-emitting elements can be extremely narrowed. Accordingly, the display panel can have high resolution or high definition.

### [Display Panel 200B]

A display panel 200B illustrated in FIG. 18 has a structure in which a transistor 310A and a transistor 310B each having a channel formed in a semiconductor substrate are stacked. Note that in the following description of display panels, the description of portions similar to those of the above-described display panel may be omitted.

In the display panel 200B, a substrate 301B provided with the transistor 310B, the capacitor 240, and the light-emitting devices is attached to a substrate 301A provided with the transistor 310A.

Here, an insulating layer 345 is provided on the bottom surface of the substrate 301B. An insulating layer 346 is provided over the insulating layer 261 over the substrate 301A. The insulating layers 345 and 346 function as protective layers and can inhibit diffusion of impurities into the substrate 301B and the substrate 301A. As the insulating layers 345 and 346, an inorganic insulating film that can be used as the protective layer 121 can be used.

The substrate 301B is provided with a plug 343 that penetrates the substrate 301B and the insulating layer 345. An insulating layer 344 functioning as a protective layer is preferably provided to cover the side surface of the plug 343.

A conductive layer 342 is provided under the insulating layer 345 on the rear surface of the substrate 301B. The conductive layer 342 is embedded in an insulating layer 335. Bottom surfaces of the conductive layer 342 and the insulating layer 335 are planarized. The conductive layer 342 is connected to the plug 343.

A conductive layer 341 is provided over the insulating layer 346 over the substrate 301A. The conductive layer 341 is embedded in an insulating layer 336. Top surfaces of the conductive layer 341 and the insulating layer 336 are planarized.

The conductive layers 341 and 342 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layers 341 and 342. In that case, it is possible to employ copper-to-copper (Cu-to-Cu) direct bonding (a technique for achieving electrical continuity by connecting copper (Cu) pads).

### [Display Panel 200C]

A display panel 200C illustrated in FIG. 19 has a structure in which the conductive layer 341 and the conductive layer 342 are bonded to each other with a bump 347.

As illustrated in FIG. 19, providing the bump 347 between the conductive layer 341 and the conductive layer 342 enables the conductive layers 341 and 342 to be connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Panel 200D]

A display panel 200D illustrated in FIG. 20 differs from the display panel 200A mainly in a structure of a transistor.

A transistor 320 is a transistor that contains a metal oxide (also referred to as an oxide semiconductor) in a semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIGS. 16A and 16B.

An insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used for at least the part of the insulating layer 326 that is in contact with the semiconductor layer 321. The top surface of the insulating layer 326 is preferably planarized.

The semiconductor layer 321 is provided over the insulating layer 326. A metal oxide film having semiconductor characteristics (also referred to as an oxide semiconductor film) is preferably used as the semiconductor layer 321. The pair of conductive layers 325 is provided on and in contact with the semiconductor layer 321, and functions as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layers 328 and 264. The insulating layer 323 that is in contact with the top surface of the semiconductor layer 321 and the conductive layer 324 are embedded in the opening portion. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are level with or substantially level with each other, and insulating layers 329 and 265 are provided to cover these layers.

The insulating layers 264 and 265 each function as an interlayer insulating layer. The insulating layer 329 functions as a barrier layer that prevents diffusion of impurities such as water or hydrogen from the insulating layer 265 or the like to the transistor 320. As the insulating layer 329, an insulating film similar to the insulating layers 328 and 332 can be used.

A plug 274 connected to one of the pair of conductive layers 325 is provided to be embedded in the insulating layers 265, 329, and 264. Here, the plug 274 preferably includes a conductive layer 274a that covers the side surface of an opening formed in the insulating layers 265, 329, 264, and 328 and part of the top surface of the conductive layer 325, and a conductive layer 274b in contact with the top surface of the conductive layer 274a. For the conductive layer 274a, a conductive material in which hydrogen and oxygen are less likely to diffuse is preferably used.

There is no particular limitation on the structure of the transistors included in the display panel of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The structure in which the semiconductor layer where a channel is formed is provided between two gates is used for the transistor 320. The two gates may be connected to each other and supplied with the same signal to drive the transistor. Alternatively, the threshold voltage of the transistor may be controlled by supplying a potential for controlling the threshold voltage to one of the two gates and supplying a potential for driving to the other of the two gates.

There is no particular limitation on the crystallinity of a semiconductor material used in the semiconductor layer of the transistor, and an amorphous semiconductor, a single crystal semiconductor, or a semiconductor having crystallinity other than single crystal (a microcrystalline semiconductor, a polycrystalline semiconductor, or a semiconductor partly including crystal regions) can be used. A single crystal semiconductor or a semiconductor having crystallinity is preferably used, in which case deterioration of the transistor characteristics can be inhibited.

The bandgap of a metal oxide used for the semiconductor layer of the transistor is preferably higher than or equal to 2 eV, further preferably higher than or equal to 2.5 eV. The use of such a metal oxide having a wide band gap can reduce the off-state current of the OS transistor.

A metal oxide preferably contains at least indium or zinc, and further preferably contains indium and zinc. The metal oxide preferably contains indium, M (M is one or more of gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example.

Alternatively, the semiconductor layer of the transistor may contain silicon. Examples of silicon include amorphous silicon and crystalline silicon (e.g., low-temperature polysilicon or single crystal silicon).

Examples of the metal oxide that can be used for the semiconductor layer include indium oxide, gallium oxide, and zinc oxide. The metal oxide preferably contain two or three kinds selected from indium, the element M, and zinc. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. Specifically, the element M is preferably one or more kinds selected from aluminum, gallium, yttrium, and tin.

Note that in the case where a metal oxide is used for the semiconductor layer, the metal oxide is preferably formed by a sputtering method or an ALD method. In the case where the metal oxide is formed by a sputtering method, the productivity and the film density can be increased. In the case where the metal oxide is formed by an ALD method, coverage with a film can be improved.

It is particularly preferable that an oxide containing indium, gallium, and zinc (also referred to as IGZO) be used as the metal oxide used for the semiconductor layer. Alternatively, it is preferable to use an oxide containing indium, tin, and zinc (also referred to as ITZO (registered trademark)). Alternatively, it is preferable to use an oxide containing indium, gallium, tin, and zinc. Alternatively, it is preferable to use an oxide containing indium, aluminum, and zinc (also referred to as IAZO). Alternatively, it is preferable to use an oxide containing indium, aluminum, gallium, and zinc (also referred to as IAGZO).

In the case where the metal oxide used for the semiconductor layer is an In-M-Zn oxide, the atomic proportion of In is preferably higher than or equal to the atomic proportion of M in the In-M-Zn oxide. Examples of the atomic ratio of the metal elements in such an In-M-Zn oxide are In:M:Zn=1:1:1, 1:1:1.2, 1:3:2, 1:3:4, 2:1:3, 3:1:2, 4:2:3, 4:2:4.1, 5:1:3, 5:1:6, 5:1:7, 5:1:8, 6:1:6, and 5:2:5 and a composition in the vicinity of any of the above atomic ratios. Note that the vicinity of the atomic ratio includes ±30% of an intended atomic ratio.

Gallium or tin is preferably used as the element M. Note that two or more of the above elements may be used in combination as the element M. For example, a metal oxide with In:M:Zn of 40:1:10 or the vicinity thereof is preferably used for the semiconductor layer. Specifically, a metal oxide with In:Sn:Zn of 40:1:10 or the vicinity thereof can be suitably used.

For example, when the atomic ratio is described as In:Ga:Zn=4:2:3 or a composition in the vicinity thereof, the case is included where the atomic proportion of Ga is greater than or equal to 1 and less than or equal to 3 and the atomic proportion of Zn is greater than or equal to 2 and less than or equal to 4 with the atomic proportion of In being 4. In addition, when the atomic ratio is described as In:Ga:Zn=5:1:6 or a composition in the vicinity thereof, the case is included where the atomic proportion of Ga is greater than 0.1 and less than or equal to 2 and the atomic proportion of Zn is greater than or equal to 5 and less than or equal to 7 with the atomic proportion of In being 5. Furthermore, when the atomic ratio is described as In:Ga:Zn=1:1:1 or a composition in the vicinity thereof, the case is included where the atomic proportion of Ga is greater than 0.1 and less than or equal to 2 and the atomic proportion of Zn is greater than 0.1 and less than or equal to 2 with the atomic proportion of In being 1.

The semiconductor layer may include two or more metal oxide layers having different compositions. For example, a stacked-layer structure of a first metal oxide layer having In:M:Zn=1:3:4 [atomic ratio] or a composition in the vicinity thereof and a second metal oxide layer having In:M:Zn=1:1:1 [atomic ratio] or a composition in the vicinity thereof and being formed over the first metal oxide layer can be suitably employed. In particular, gallium or aluminum is preferably used as the element M.

Alternatively, a stacked-layer structure or the like of one selected from indium oxide, indium gallium oxide, and IGZO, and one selected from IAZO, IAGZO, and ITZO (registered trademark) may be used, for example.

As examples of the oxide semiconductor having crystallinity, a c-axis aligned crystalline oxide semiconductor (CAAC-OS), a nanocrystalline oxide semiconductor (nc-OS), and the like are given.

An OS transistor has much higher field-effect mobility than a transistor containing amorphous silicon. In addition, the OS transistor has an extremely low leakage current between a source and a drain in an off state (the leakage current is also referred to as an off-state current), and charge accumulated in a capacitor that is connected in series to the transistor can be retained for a long period. Furthermore, the power consumption of the display panel can be reduced with the OS transistor.

To increase the emission luminance of the light-emitting device included in the pixel circuit, the amount of a current flowing through the light-emitting device needs to be increased. To increase the current amount, the source-drain voltage of a driving transistor included in the pixel circuit needs to be increased. An OS transistor has a higher breakdown voltage between a source and a drain than a Si transistor; hence, a high voltage can be applied between the source and the drain of the OS transistor. Thus, with use of an OS transistor as the driving transistor included in the pixel circuit, the amount of a current flowing through the light-emitting device can be increased, resulting in an increase in emission luminance of the light-emitting device.

Assuming that the transistor operates in a saturation region, a change in the amount of a current between the source and the drain, with respect to a fluctuation in the gate-source voltage, in the OS transistor is smaller than that in the Si transistor. Accordingly, when an OS transistor is used as the driving transistor in the pixel circuit, a current flowing between the source and the drain can be set minutely in accordance with a change in gate-source voltage; hence, the amount of a current flowing through the light-emitting device can be controlled. Consequently, the number of gray levels expressed by the pixel circuit can be increased.

Regarding saturation characteristics of a current flowing when a transistor operates in a saturation region, a current (saturation current) can flow more stably in an OS transistor than in a Si transistor even when the source-drain voltage gradually increases. Thus, with the use of an OS transistor as the driving transistor, a current can be made to flow stably through the light-emitting device, for example, even when a variation in current-voltage characteristics of the EL device occurs. In other words, when the OS transistor operates in the saturation region, the source-drain current hardly changes with an increase in the source-drain voltage; hence, the emission luminance of the light-emitting device can be stable.

As described above, with the use of an OS transistor as the driving transistor included in the pixel circuit, it is possible to achieve “reduction in power consumption”, “increase in emission luminance”, “increase in gray level”, “inhibition of variation in light-emitting devices”, and the like.

### [Display Panel 200E]

A display panel 200E illustrated in FIG. 21 has a structure in which the transistor 310 having a channel formed in the substrate 301 and the transistor 320 containing a metal oxide in a semiconductor layer where a channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are connected to each other through the plug 274.

The transistor 320 can be used as a transistor included in the pixel circuit. The transistor 310 can be used as a transistor included in the pixel circuit or a transistor included in a driver circuit for driving the pixel circuit (a gate line driver circuit or a source line driver circuit). The transistor 310 and the transistor 320 can also be used as transistors included in a variety of circuits such as an arithmetic circuit and a memory circuit.

With such a structure, not only the pixel circuit but also the driver circuit and the like can be formed directly under the light-emitting devices; thus, the display panel can be downsized as compared with the case where a driver circuit is provided around a display region.

### [Display Panel 200F]

A display panel 200F illustrated in FIG. 22 has a structure in which the transistor 320 in the display panel 200E illustrated in FIG. 21 is replaced with a transistor 320A (vertical transistor). Note that the structure in which the transistor 320 is replaced with the transistor 320A can also be employed for the display panel 200D illustrated in FIG. 20.

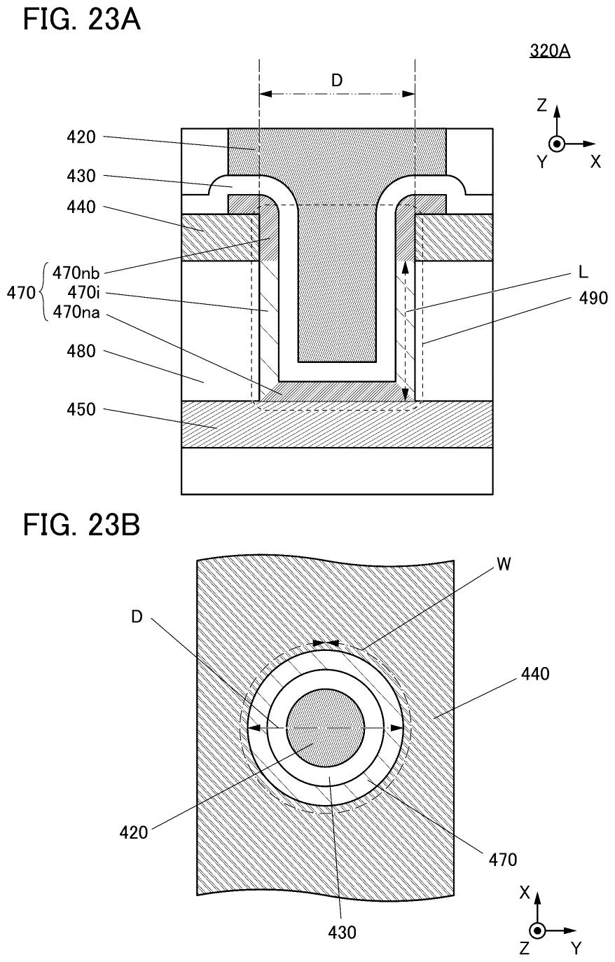

FIG. 23A is a cross-sectional view of the transistor 320A along the X-Z plane. FIG. 23B is a cross-sectional view along the X-Y plane including a wiring 440.

The transistor 320A includes an oxide semiconductor 470, an insulator 430, and a conductor 420. The oxide semiconductor 470 functions as a semiconductor layer, the insulator 430 functions as a gate insulator, and the conductor 420 functions as a gate electrode. A wiring 450 includes a region that functions as one of a source electrode and a drain electrode of the transistor 320A. The wiring 440 includes a region that functions as the other of the source electrode and the drain electrode of the transistor 320A.

An opening portion 490 penetrating through the wiring 440 and an insulator 480 and reaching the wiring 450 is provided. The opening portion 490 has a pillar shape with a substantially circular top surface. This structure enables miniaturization or high integration of the memory cell. Note that the side surface of the opening portion 490 is preferably perpendicular to the top surface of the wiring 450.

At least part of the oxide semiconductor 470 is provided in the opening portion 490. Note that the oxide semiconductor 470 includes a region in contact with the top surface of the wiring 450, a region in contact with the side surface of the wiring 440, and a region in contact with the side surface of the insulator 480 in the opening portion 490.

The insulator 430 is provided so as to at least partly cover the opening portion 490. The conductor 420 is provided so that at least part of the conductor 420 is positioned in the opening portion 490. The conductor 420 is preferably provided so as to be embedded in the opening portion 490, and the shape of the conductor 420 in the top view is preferably substantially circular for a higher integration degree.

As illustrated in FIG. 23A, the oxide semiconductor 470 includes a region 470i and regions 470na and 470nb provided with the region 470i positioned therebetween.

The region 470na is a region in contact with the wiring 450 in the oxide semiconductor 470. At least part of the region 470na functions as one of the source region and the drain region of the transistor 320A. The region 470nb is a region in contact with the wiring 440 in the oxide semiconductor 470. At least part of the region 470nb functions as the other of the source region and the drain region of the transistor 320A. As illustrated in FIG. 23B, the wiring 440 is in contact with all the perimeter of the oxide semiconductor 470. Thus, the other of the source region and the drain region of the transistor 320A can be formed along all the perimeter of a region formed in the same layer as the wiring 440 in the oxide semiconductor 470.

The region 470i is a region positioned between the region 470na and the region 470nb in the oxide semiconductor 470. At least part of the region 470i functions as the channel formation region of the transistor 320A. That is, the channel formation region of the transistor 320A is formed in part of the oxide semiconductor 470 that is positioned in a region between the wiring 450 and the wiring 440. It can be said that the channel formation region of the transistor 320A is positioned in a region in contact with the insulator 480 or a region in the vicinity thereof in the oxide semiconductor 470.

The channel length of the transistor 320A is a distance between the source region and the drain region. That is, the channel length of the transistor 320A is determined by the thickness of the insulator 480 over the wiring 450. In FIG. 23A, a channel length L of the transistor 320A is indicated by a dashed double-headed arrow. The channel length L is a distance between an end portion of a region where the oxide semiconductor 470 and the wiring 450 are in contact with each other and an end portion of a region where the oxide semiconductor 470 and the wiring 440 are in contact with each other in a cross-sectional view. That is, the channel length L corresponds to the length of the side surface of the insulator 480 on the opening portion 490 side in the cross-sectional view.

The channel length of a planar transistor is limited by the light exposure limit of photolithography, and further miniaturization is difficult. In contrast, in one embodiment of the present invention, the channel length can be determined by the thickness of the insulator 480. Thus, the transistor 320A can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 320A can have a high on-state current.

In addition, as described above, the channel formation region, the source region, and the drain region can be formed in the opening portion 490. Thus, the area occupied by the transistor 320A can be reduced as compared with a conventional transistor in which the channel formation region, the source region, and the drain region are provided separately on the X-Y plane. In addition, the pixel density can be increased.

The transistor including the channel formation region along the side surface of the insulator 480 in the opening portion 490 in the above-described manner is referred to as a vertical transistor.

Furthermore, in the X-Y plane including the channel formation region of the oxide semiconductor 470, as illustrated in FIG. 23B, the oxide semiconductor 470, the insulator 430, and the conductor 420 are provided concentrically. Therefore, the side surface of the conductor 420 provided at the center faces a side surface of the oxide semiconductor 470 with the insulator 430 therebetween. That is, in the top view, all the perimeter of the oxide semiconductor 470 serves as the channel formation region. In this case, for example, the channel width of the transistor 320A is determined by the length of the perimeter of the oxide semiconductor 470. In other words, the channel width of the transistor 320A is determined by the maximum width of the opening portion 490 (the maximum diameter in the case where the opening portion 490 is circular in the top view). In FIGS. 23A and 23B, a maximum width D of the opening portion 490 is indicated by a dashed double-dotted double-headed arrow. In FIG. 23B, a channel width W of the transistor 320A is indicated by a dashed-dotted double-headed arrow. By increasing the maximum width D of the opening portion 490, the channel width per unit area can be increased and the on-state current can be increased.

In the case where the opening portion 490 is formed by a photolithography method, the maximum width D of the opening portion 490 is limited by the light exposure limit of photolithography. In addition, the maximum width D of the opening portion 490 is determined by the film thicknesses of the oxide semiconductor 470, the insulator 430, and the conductor 420 provided in the opening portion 490. The maximum width D of the opening portion 490 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 490 is circular in the top view, the maximum width D of the opening portion 490 corresponds to the diameter of the opening portion 490, and the channel width W can be “D′π”.

In the memory device of one embodiment of the present invention, the channel length L of the transistor 320A is preferably shorter than at least the channel width W of the transistor 320A. The channel length L of the transistor 320A in one embodiment of the present invention is greater than or equal to 0.1 times and less than or equal to 0.99 times, preferably greater than or equal to 0.5 times and less than or equal to 0.8 times the channel width W of the transistor 320A. This structure enables a transistor with favorable electrical characteristics and high reliability.

In the case where the opening portion 490 is formed to be substantially circular in the top view, the oxide semiconductor 470, the insulator 430, and the conductor 420 are formed concentrically. This makes the distance between the conductor 420 and the oxide semiconductor 470 substantially uniform, so that a gate electric field can be substantially uniformly applied to the oxide semiconductor 470.

It is preferable that the channel formation region of the transistor including an oxide semiconductor in the semiconductor layer contain less oxygen vacancies or have a lower concentration of impurities such as hydrogen, nitrogen, or a metal element than the source region and the drain region. For example, the concentration of aluminum in the channel formation region of the oxide semiconductor is preferably lower than or equal to 1×10²² atoms/cm³, further preferably lower than or equal to 1×10²¹ atoms/cm³, still further preferably lower than or equal to 1×10²⁰ atoms/cm³, yet further preferably lower than or equal to 5×10¹⁹ atoms/cm³, yet still further preferably lower than or equal to 1×10¹⁹ atoms/cm³, yet still further preferably lower than or equal to 5×10¹⁸ atoms/cm³, yet still further preferably lower than or equal to 1×10¹⁸ atoms/cm³.

In some cases, hydrogen in the vicinity of an oxygen vacancy forms a defect that is an oxygen vacancy into which hydrogen enters (hereinafter sometimes referred to as VoH), which generates an electron serving as a carrier. Thus, it is preferable that the amount of VoH be also reduced in the channel formation region. Thus, the channel formation region of the transistor is a high-resistance region having a low carrier concentration. Accordingly, the channel formation region of the transistor can be regarded as an i-type (intrinsic) or substantially i-type region.

The source region and the drain region of the transistor including an oxide semiconductor in the semiconductor layer are regions which have lower resistances than the channel formation region by having increased carrier concentrations because of containing more oxygen vacancies or more V_{O}H or having higher concentrations of impurities such as hydrogen, nitrogen, or a metal element. In other words, the source region and the drain region of the transistor are n-type regions having higher carrier concentrations and lower resistances than the channel formation region.

Although the opening portion 490 is provided so that the side surface of the opening portion 490 is perpendicular to the top surface of the wiring 450 in FIG. 23A and the like, the present invention is not limited thereto. For example, the side surface of the opening portion 490 may have a tapered shape.

At least part of this embodiment can be implemented in combination with the other embodiment described in this specification as appropriate.

This application is based on Japanese Patent Application Serial No. 2024-024199 filed with Japan Patent Office on Feb. 21, 2024, the entire contents of which are hereby incorporated by reference.

What is claimed is:

1. A display apparatus comprising:
a pixel comprising a first subpixel, a second subpixel, and a third subpixel emitting light of different colors;
a first plano-convex lens over the first subpixel;
a second plano-convex lens over the second subpixel; and
a third plano-convex lens and a fourth plano-convex lens over the third subpixel,
wherein the first subpixel and the second subpixel are adjacent to each other in a first direction,
wherein the third subpixel is adjacent to each of the first subpixel and the second subpixel in a second direction intersecting with the first direction perpendicularly, and
wherein the third plano-convex lens and the fourth plano-convex lens are adjacent to each other in the first direction.

2. The display apparatus according to claim 1,
wherein the third plano-convex lens is adjacent to the first plano-convex lens in the second direction,
wherein the fourth plano-convex lens is adjacent to the second plano-convex lens in the second direction,
wherein the first plano-convex lens and the fourth plano-convex lens each have a circular outline with a radius r₁ in a top view,
wherein the second plano-convex lens and the third plano-convex lens each have a circular outline with a radius r₂ in the top view,
wherein the pixel has a square shape in the top view, and
wherein a length of one side of the pixel is larger than or equal to 2(r₁+r₂).

3. The display apparatus according to claim 1,
wherein a region of the third plano-convex lens is over an adjacent pixel.

4. The display apparatus according to claim 1,
wherein the first plano-convex lens, the second plano-convex lens, the third plano-convex lens, and the fourth plano-convex lens are each a spherical lens.

5. The display apparatus according to claim 1,
wherein the third subpixel has a rectangular shape in the top view,
wherein a center point of each of the third plano-convex lens and the fourth plano-convex lens is on or in a vicinity of a straight line perpendicularly dividing a short side of the third subpixel in the top view,
wherein the center point of the third plano-convex lens is with a distance of r₂ from a center point of the third subpixel or in the vicinity thereof in the top view, and
wherein the center point of the fourth plano-convex lens is with a distance of r₁ from the center point of the third subpixel or in the vicinity thereof in the top view.

6. The display apparatus according to claim 1,
wherein the first subpixel emits red light,
wherein the second subpixel emits green light, and
wherein the third subpixel emits blue light.

7. A display apparatus comprising:
a pixel comprising a first subpixel, a second subpixel, and a third subpixel emitting light of different colors;
a first plano-convex lens over the first subpixel;
a second plano-convex lens over the second subpixel; and
a lens array comprising a third plano-convex lens, a fourth plano-convex lens, and a fifth plano-convex lens over the third subpixel,
wherein the first subpixel and the second subpixel are adjacent to each other in a first direction,
wherein the third subpixel is adjacent to each of the first subpixel and the second subpixel in a second direction intersecting with the first direction perpendicularly,
wherein the third plano-convex lens, the fourth plano-convex lens, and the fifth plano-convex lens which are different from one another are bonded in the first direction, and
wherein the lens array comprises a first lens region, a second lens region, and a third lens region having different curvatures in the first direction.

8. The display apparatus according to claim 7,
wherein the first lens region comprises a region with a first curvature,
wherein the second lens region comprises a region with a second curvature,
wherein the third lens region comprises a region with a third curvature,
wherein the region with the first curvature has a curvature equivalent to a curvature of the second plano-convex lens,
wherein the region with the third curvature has a curvature equivalent to a curvature of the first plano-convex lens, and
wherein the second lens region has a curvature in a range between the curvature of the first plano-convex lens and the curvature of the second plano-convex lens.

9. The display apparatus according to claim 7,
wherein the first lens region is adjacent to the first plano-convex lens in the second direction,
wherein the third lens region is adjacent to the second plano-convex lens in the second direction,
wherein the first plano-convex lens has a circular outline with a radius r₁ in a top view,
wherein the second plano-convex lens has a circular outline with a radius r₂ in the top view,
wherein the pixel has a square shape in the top view, and
wherein a length of one side of the pixel is larger than or equal to 2(r₁+r₂).

10. The display apparatus according to claim 7,
wherein a region of the lens array is over an adjacent pixel.

11. The display apparatus according to claim 7,
wherein the third subpixel has a rectangular shape in the top view,
wherein a center point of each of the first lens region, the second lens region, and the third lens region is on or in a vicinity of a straight line perpendicularly dividing a short side of the third subpixel in the top view, and
wherein the center point of the second lens region is at or in a vicinity of a center point of the third subpixel in the top view.

12. The display apparatus according to claim 7,
wherein the first subpixel emits red light,
wherein the second subpixel emits green light, and
wherein the third subpixel emits blue light.

13. An electronic device comprising the display apparatus according to claim 7,
wherein the display apparatus is a light source, and
wherein a catadioptric system is on a display surface side of the display apparatus.
